(19) United States
(12) Patent Application Publication
(10) Pub. No.: US 2023/0399197 A1
(43) Pub. Date: Dec. 14, 2023

(54) STACKABLE NON-INTRUSIVE DEVICE FOR TOUCHLESS OPERATION OF AN ELEVATOR THROUGH FINGER GESTURES

(71) Applicant: ELM, Riyadh (SA)

(72) Inventors: Syed Salman ALAM, Riyadh (SA); Bassam ALBAHRA, Riyadh (SA); Arshad Ali KHAN, Riyadh (SA); Riad SOUISSI, Riyadh (SA); Mohammed Mahmoud Abdulkader KHAN, Riyadh (SA)

(73) Assignee: ELM, Riyadh (SA)

(21) Appl. No.: 18/295,894

(22) Filed: Apr. 5, 2023

Related U.S. Application Data
(60) Provisional application No. 63/350,620, filed on Jun. 9, 2022.

(51) Int. Cl. B66B 1/52; G06F 3/01; B66B 3/00; H01H 13/14

(52) U.S. Cl. CPC B66B 1/52; G06F 3/017; B66B 3/002; H01H 13/14; B66B 2201/4638; B66B 2201/4623

(57) ABSTRACT

A stackable, non-contact device for operating elevator buttons is described. The non-contact device includes a servo mechanism with a dual-arm configured to press either of two elevator buttons. Two proximity sensors are configured to register the approach of a finger touch of either proximity sensor, which commands the servo mechanism to press the corresponding elevator button. The stackable, non-contact device includes a microcontroller configured to receive near field communications from a mobile application, which includes commands for pressing a specific elevator button.

### CROSS REFERENCE TO RELATED APPLICATIONS

The present application claims the benefit of priority to U.S. Provisional Application No. 63/350,620, entitled “Stackable Non-Intrusive Device To Facilitate Touchless Operation Of An Elevator Through Finger Gestures”, filed on Jun. 9, 2022, and incorporated herein by reference in its entirety.

### BACKGROUND

### TECHNICAL FIELD

The present disclosure is directed to a stackable, non-intrusive device to facilitate touchless operation of an elevator. The device is configured for aftermarket attachment to existing elevator control panels.

### DESCRIPTION OF RELATED ART

The “background” description provided herein is for the purpose of generally presenting the context of the disclosure. Work of the presently named inventors, to the extent it is described in this background section, as well as aspects of the description which may not otherwise qualify as prior art at the time of filing, are neither expressly or impliedly admitted as prior art against the present invention.

COVID-19 spreads rapidly and has caused infection, deaths, and disruption to business and infrastructure. Countries across the world have been affected and are still reeling from the after-effects of the pandemic in terms of long-term health problems, joblessness, infectious diseases, travel restrictions, and uncontrolled inflation. While mass vaccination has drastically reduced the spread of the virus, the virus still remains active, and cautions are being observed to protect the vulnerable, the elderly, and those with a high risk of infection due to weak immune systems. It has been necessary to observe preventive protocols while fulfilling the needs of daily life e.g., going to workplaces, participating in events, going out to shopping malls and sports venues, etc.

The difference between a symptomatic and asymptomatic spreader of the virus further complicates the situation. A virus may be left on various surfaces by a carrier of the virus and others may be exposed by touching that surface. The interaction with the affected surface may happen due to a specific need in a workplace, educational institution or while living in a communal residential community/area. Surfaces such as a door handle, elevator buttons, and a shopping cart handle are examples of surfaces touched by multiple people in quick succession, which may be a source for spreading the virus.

In a pandemic-hit world, one of the most common sources of spreading a virus such as COVID-19 is by being in a public place, using a public facility, transport, or shared office space etc. One such public space, which is very constrained, and used by a high number of people during office hours is an elevator. Elevator button panels are heavily used surfaces where users interact with buttons by touching the buttons with their fingertips. Finger-pressed buttons are a source of contamination which may spread a contagious virus such as COVID-19 in a short exposure time. Transforming and replacing existing elevators with touchless button panels may not be feasible for many organizations given the cost, time, and technological complexities (e.g., legacy versus modern system design, etc.) involved at all levels.

However, due to the continuing COVID-19 pandemic, immediate steps are needed to reduce exposure from contact with surfaces, such as elevator buttons, which are touched by many people during the course of a day, and which may be a source of spreading the COVID-19 virus.

Some solutions have been proposed to solve the problem by providing touchless contact panels.

U.S. Pat. No. 8,872,387B2 describes a non-contact selection switch for an elevator and a selection switch method which is implemented by using 2 long sensor blocks adjacent to each other. The sensor detects the movement of the fingers going upwards or downwards. However, the non-contact switch must be integrated into the elevator control panel, which cannot be easily accomplished and may void the warranty on the control panel.

KR20170136176A describes a non-contact sensor comprising a proximity panel for an elevator door. However, the proximity panel must be integrated into the elevator door control structure, thus requiring modification of the door structure.

U.S. Pat. No. 9,733,763B2 describes a portable device using a passive proximity sensor for initiating touchless gesture control of a computer touch screen as sensed by a camera detecting changing light patterns. The changing light patterns are analyzed to control a computer. However, this system does not solve the problem of non-contact control of elevator buttons and would not be able to be used as an aftermarket attachment to an elevator button control panel.

Accordingly, it is one object of the present disclosure to provide methods and systems for a stackable non-intrusive device that facilitates touchless operation of an elevator through finger gestures, which can be installed in a variety of elevator systems.

### SUMMARY

In an embodiment, a non-contact system for operating elevator buttons is described. The non-contact system includes a first non-contact device. The first non-contact device includes a motor, a battery, a voltage regulator, a motor shaft, a dual arm, a first protrusion, a second protrusion, a switch, a first proximity sensor, a second proximity sensor, and a microcontroller. The battery is switchably connected to the motor. The motor shaft is connected to the motor. The motor shaft is configured to rotate when the battery is connected to the motor. The dual arm is connected to the motor shaft at a center of the arm. The dual arm has a first end and a second end. The dual arm is configured to rotate with the motor shaft. The first protrusion is connected to the first end. The first protrusion extends perpendicularly from the first end and is configured to depress a first elevator button. The second protrusion is connected to the second end. The second protrusion extends perpendicularly from the second end and is configured to depress a second elevator button. The switch is operatively connected to the motor. The first proximity sensor is configured to detect a first finger gesture and generate a first signal. The second proximity sensor is configured to detect a second finger gesture and generate a second signal. The microcontroller is connected to the switch, the first proximity sensor and the second proximity sensor. The microcontroller includes an electrical circuitry, a memory including program instructions and at least one processor configured to execute the program instructions to: actuate the switch to cause the motor to rotate the dual arm in a first direction to press the first elevator button when the first signal is received; and actuate the switch to cause the motor to rotate the dual arm in a second direction to press the second elevator button when the second signal is received, wherein the second direction is rotationally opposite the first direction.

In another embodiment, a stackable master-slave non-contact system for operating elevator buttons is described. The stackable master-slave non-contact system includes a plurality of non-contact devices. Each non-contact device includes a motor, a battery switchably connected to the motor, a voltage regulator connected to the battery, a motor shaft connected to the motor, wherein the motor shaft is configured to rotate when the battery is connected to the motor, a dual arm connected to the motor shaft at a center of the arm, wherein the dual arm has a first end and a second end, wherein the dual arm is configured to rotate with the motor shaft; a first protrusion connected to the first end, wherein the first protrusion extends perpendicularly from the first end, wherein the first protrusion is configured to depress a first elevator button; a second protrusion connected to the second end, wherein the second protrusion extends perpendicularly from the second end, wherein the second protrusion is configured to depress a second elevator button; a switch operatively connected to the motor; a first proximity sensor configured to detect a first finger gesture and generate a first signal; a second proximity sensor configured to detect a second finger gesture and generate a second signal; a microcontroller connected to the switch, the first proximity sensor and the second proximity sensor, wherein the microcontroller includes an electrical circuitry, a memory including program instructions and at least one processor configured to execute the program instructions to: actuate the switch to cause the motor to rotate the dual arm in a first direction to press the first elevator button when the first signal is received; and actuate the switch to cause the motor to rotate the dual arm in a second direction to press the second elevator button when the second signal is received, wherein the second direction is rotationally opposite the first direction. The non-contact device also includes a first light emitting diode; and a second light emitting diode. The microcontroller is connected to the first light emitting diode and the second light emitting diode, wherein the microcontroller is configured to switch ON the first light emitting diode when the first signal is received and switch ON the second light emitting diode when the second signal is received. The non-contact device also includes a near field communication receiver operatively connected to the microcontroller, wherein the near field communication receiver is configured to receive first commands from a mobile application installed on a mobile computing device within a near field communication range when the near field communication receiver is turned ON, wherein the microcontroller is further configured to switch the motor to rotate the dual arm in one of the first direction to press the first elevator button and the second direction to press the second elevator button based on the first commands; and a buffer circuit connected between the microcontroller and the motor, wherein the buffer circuit is configured to store a usage count and increase the usage count when one of the first signal and the second signal are received by the microcontroller.

In another embodiment, a method for using a stackable master-slave non-contact system for operating elevator buttons is described. The method includes operatively stacking a plurality of non-contact devices onto the surface of an elevator control panel so that the each of the plurality of non-contact devices is adjacent to a pair of elevator buttons. For each of the plurality of non-contact devices, the method includes monitoring, by a microcontroller of the non-contact device, a first proximity sensor for a first signal and a second proximity sensor for a second signal. The method further includes receiving, by the microcontroller one of the first signal and the second signal. The method further includes updating, by a buffer circuit connected to the microcontroller, a usage count of a buffer circuit upon receiving one of the first signal and the second signal. The method further includes actuating, by the microcontroller, a motor configured to rotate a dual arm connected to the motor in one of a first rotational direction such that a first protrusion presses a first elevator button based on the first signal and in a second rotational direction such that a second protrusion presses a second elevator button based on the second signal. The method further includes switching ON a first light emitting diode adjacent to the first proximity sensor upon receiving the first signal and switching ON a second light emitting diode adjacent to the second proximity sensor upon receiving the second signal.

The foregoing general description of the illustrative embodiments and the following detailed description thereof are merely exemplary aspects of the teachings of this disclosure and are not restrictive.

### BRIEF DESCRIPTION OF THE DRAWINGS

A more complete appreciation of this disclosure and many of the attendant advantages thereof will be readily obtained as the same becomes better understood by reference to the following detailed description when considered in connection with the accompanying drawings, wherein:

FIG. 1A is a network diagram of a non-contact system for operating elevator buttons, according to aspects of the present disclosure;

FIG. 1B is a block diagram of a non-contact device, according to aspects of the present disclosure;

FIG. 1C is an exemplary illustration of a top view of the non-contact device, according to aspects of the present disclosure;

FIG. 2 illustrates an assembly having a plurality of interconnected non-contact devices, according to aspects of the present disclosure;

FIG. 3 is an exemplary illustration of an output connector panel of the non-contact device, according to aspects of the present disclosure;

FIG. 4 is an exemplary illustration of an input connector panel of the non-contact device, according to aspects of the present disclosure;

FIG. 5A is an exemplary illustration of the top view of the non-contact device, according to aspects of the present disclosure;

FIG. 5B is an exemplary illustration of a side view of the non-contact device, according to aspects of the present disclosure;

FIG. 5C is another exemplary illustration of another side view of the non-contact device, according to aspects of the present disclosure;

FIG. 6A is another exemplary illustration of the bottom view of the non-contact device, according to aspects of the present disclosure;

FIG. 6B is an exemplary illustration of the top view of the non-contact device, according to aspects of the present disclosure;

FIG. 7A illustrates an interior of a housing of the non-contact device when the top surface is removed, according to aspects of the present disclosure;

FIG. 7B shows assembled components inside the non-contact device when the top surface is removed, according to aspects of the present disclosure;

FIG. 7C illustrates a bottom side of the printed circuit board, according to aspects of the present disclosure;

FIG. 7D illustrates a motor connection and motor slot inside the non-contact device when the top surface is removed, according to aspects of the present disclosure;

FIG. 8A illustrates a 3D model of an enclosure of the non-contact device, according to aspects of the present disclosure;

FIG. 8B illustrates a 3D vertical cross-sectional view of the housing of the non-contact device, according to aspects of the present disclosure;

FIG. 8C illustrates a 3D horizontal cross-sectional view of the housing of the non-contact device, according to aspects of the present disclosure;

FIG. 9A is an exemplary illustration of the non-contact system having three stacked non-contact devices, according to aspects of the present disclosure;

FIG. 9B is an exemplary illustration of an installed non-contact system, according to aspects of the present disclosure;

FIG. 10 is another exemplary illustration of an installed non-contact system, according to aspects of the present disclosure;

FIG. 11 is a flowchart of a device configuration selection process, according to aspects of the present disclosure;

FIG. 12 is a flowchart of a master device process flow, according to aspects of the present disclosure;

FIG. 13 is a flowchart of a slave device process flow, according to aspects of the present disclosure;

FIG. 14 is an illustration of a non-limiting example of details of computing hardware used in the computing system, according to aspects of the present disclosure;

FIG. 15 is an exemplary schematic diagram of a data processing system used within the computing system, according to aspects of the present disclosure;

FIG. 16 is an exemplary schematic diagram of a processor used with the computing system, according to aspects of the present disclosure; and

FIG. 17 is an illustration of a non-limiting example of distributed components that may share processing with the controller, according to aspects of the present disclosure.

### DETAILED DESCRIPTION

In the drawings, like reference numerals designate identical or corresponding parts throughout the several views. Further, as used herein, the words “a,” “an” and the like generally carry a meaning of “one or more,” unless stated otherwise.

Furthermore, the terms “approximately,” “approximate,” “about,” and similar terms generally refer to ranges that include the identified value within a margin of 20%, 10%, or preferably 5%, and any values therebetween.

The present disclosure describes an elevator control panel that is designed to mitigate the spread of contagious disease, such as the COVID-19 virus, in enclosed spaces such as public elevators. The elevator control panel is a surface that is used by a large number of people daily who touch/press various floor buttons. The buttons are a frequently touched surface and may be a conduit for spreading COVID-19 and other communicable diseases. Several elevator manufacturing companies have built elevators having proximity sensors or interact with mobile applications to manipulate the elevator buttons, however such embedded sensors are integral to the elevator system and cannot be used in legacy elevator systems. Further, each smart elevator proximity sensor panel interacts differently in the case of each manufacturer thus making it difficult to develop a single generic proximity sensing platform. Some options require modifying the existing elevator with circuitry modifications and enabling connections in the panel board. However, that solution has its own drawback as it might void the original equipment warranty and may cause regulation breaches. Changing or repurposing an existing elevator to incorporate button sensing capabilities may lead to complications involving a high cost of modification.

To contribute to preventative care and reduce the spread of the virus, while using public places like an elevator, the present disclosure describes aspects of the development, testing, manufacture, structure, design and deployment of a touchless elevator control panel device for aftermarket use with existing elevators. The device, system and method described in the present disclosure can help reduce the spread of infection by providing a touchless and gesture-controlled elevator control panel device.

The term “non-contact” as used herein refers to a system or device which can be operated without physically touching the system or device. The term “non-contact” may also be referred to as “touchless” or as “touch free”.

Aspects of the present disclosure describe a non-contact system for operating elevator buttons that is stackable with another unit and/or system to enable the operation of a multi-floor elevator using hand and finger gestures. The non-contact system is adaptable to a conventional elevator button panel, where each button is for a specific floor inside a multi-floor building. The non-intrusive nature of the non-contact system makes it more unique and easier to deploy in heterogeneous elevators. The non-contact system can be seamlessly used with any design of elevator button controls which are lined up in a row or column.

Aspects of the present disclosure provide a solution to the need to configure the electronic modular unit for each elevator panel. The electronic modular unit comprises a master board with multiple slave boards that can be stacked in series with the master board or arranged cumulatively with the master board and deployed systematically. Any device can work as the master board. The device configure itself as a slave or master based on the configuration of installation. During installation on an elevator panel, the first electronic modular unit installed is the master board.

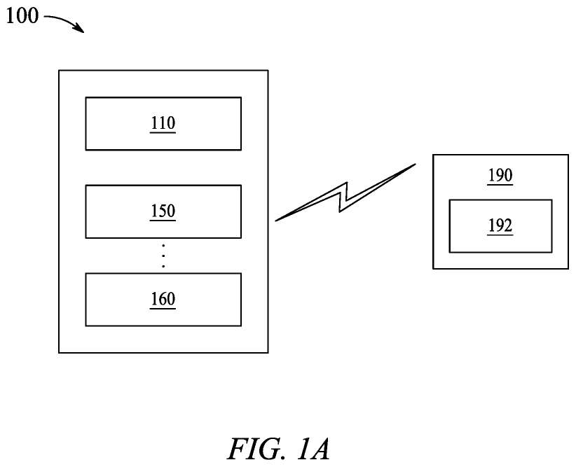

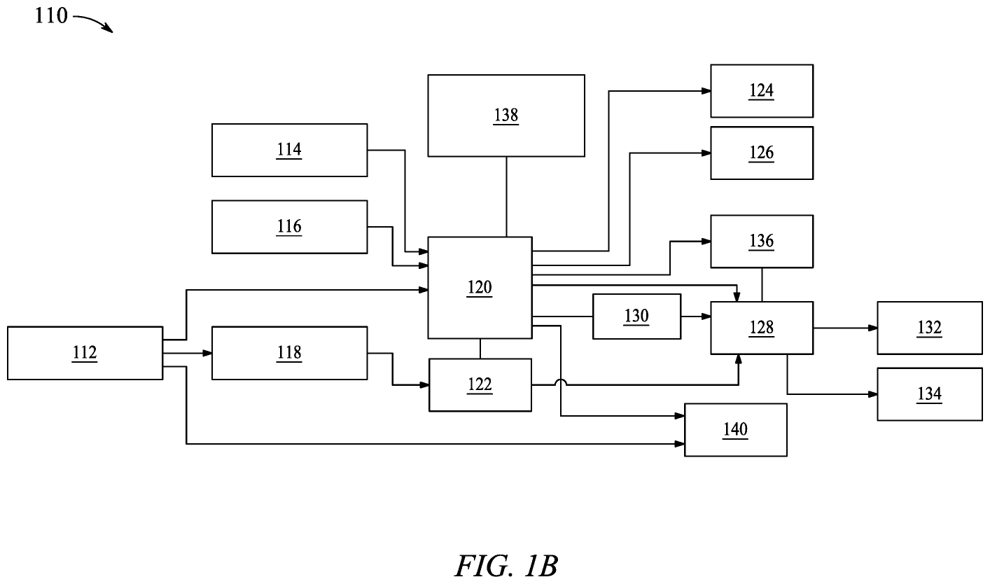

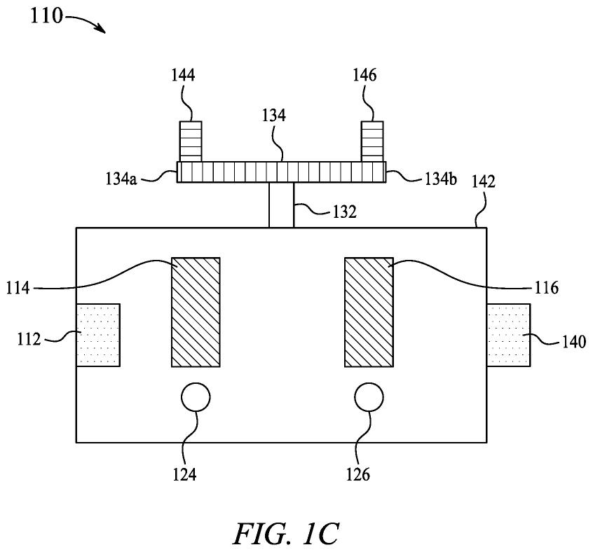

FIG. 1A is a network diagram of a non-contact system 100 for operating elevator buttons (hereinafter interchangeably referred to as “the system 100”), according to one or more aspects of the present disclosure. The system 100 includes a plurality of non-contact devices (110, 150, 160), and a mobile computing device 190. In an exemplary aspect, the plurality of non-contact devices (110, 150, 160) includes a first non-contact device 110, a second non-contact device 150, and a third non-contact device 160.

Each non-contact device (110, 150, 160) includes a housing. Each non-contact device (110, 150, 160) has at least two proximity sensors and a motor with a dual arm and/or extension. The housing is configured to house a number of components such as a motor, a motor shaft, a first proximity sensor, a second proximity sensor, and a microcontroller. The housing is made of material that is preferably rust-free, or non-rusting, corrosion-resistant and/or acid-resistant. The housing may be made of plastic, an insulating material, or metal, such as galvanized steel. The motor shaft is connected to the motor. The motor shaft is configured to rotate. Each non-contact device (110, 150, 160) is substantially similar in form factor with associated connectors and can be stacked to connect multiple units up to 250 units.

To operate the non-contact device to operate an elevator button, a user covers, without touching, the proximity sensor of a desired floor for a predetermined length of time, e.g., 1.5 seconds. Once the non-contact device senses that the button needs pressing, the non-contact device uses the motor with the dual arm to press the button as required.

In an operational aspect, each non-contact device (110, 150, 160) is configured to receive a user input in two ways: by detecting the hand or finger gesture and/or by receiving commands from the mobile computing device 190. When a finger of the user comes within a sensing range of the proximity sensor, the first proximity sensor and the second proximity sensor are configured to detect a finger gesture. Depending on the ranges of the first proximity sensor and the second proximity sensor, each proximity sensor may detect the finger gesture. Based on detection of a first finger gesture in range of the first proximity sensor or a second finger gesture in range of the second proximity sensor, the first proximity sensor generates a first signal and/or the second proximity sensor generates a second signal, respectively. The microcontroller may determine which proximity sensor was actuated based on a relative intensity of the first signal and the second signal or by comparing each of the first signal and the second signal to an activation threshold.

The microcontroller is connected to the motor, the motor shaft, the first proximity sensor, and the second proximity sensor. The microcontroller is configured to receive the first signal or the second signal from the first proximity sensor and the second proximity sensor, respectively. On receiving the first signal, the microcontroller is configured to actuate a switch to cause the motor to move (e.g., elevate, depress and/or rotate) the dual arm in a first direction to press a first elevator button. On receiving the second signal, the microcontroller is configured to actuate the switch to cause the motor to move the dual arm in a second direction to press a second elevator button. In an example, the second direction is rotationally opposite to the first direction.

Each of the non-contact devices (110, 150, 160) is a stackable block for operating elevator buttons. The plurality of non-contact devices (110, 150, 160) is configured to make a stackable configuration which is configured to cover and/or operate one or more buttons of the elevator panel according to the need of the user. In a configuration, each non-contact device may be configured to control at least two elevator buttons. The stackable configuration can be attached to the elevator panel such that the configuration can cover all of the buttons of the elevator panel. The stackable, non-contact device can be installed on any non-contact sensor elevator button control panel to convert the panel to a touchless panel.

The mobile computing device 190 is configured to interact with the each of the non-contact devices (110, 150, 160) via a mobile application 192. In an example, the user may download and install the mobile application on the mobile computing device 190. In some examples, the mobile application may be a software application, or a mobile application for operating elevator buttons and provided by an application distribution platform. Examples of mobile application distribution platforms include the App Store for iOS provided by Apple, Inc., Play Store for Android OS provided by Google Inc., and such application distribution platforms.

Each of the non-contact devices (110, 150, 160) includes a near field communication receiver that is operatively connected to the microcontroller. One of the non-contact devices is designated as a master device and the other non-contact devices connected to the master device are designated as slave devices. The microcontroller turns ON the near field communication receiver of the master device but does not turn ON the near field communication receiver of any of the slave devices. The near field communication receiver is configured to detect the presence of the mobile computing device 190 within a near field communication range. In an operative aspect, a user may send a control signal (first commands and second commands) to the microcontroller of the master device using the mobile application 192. The near field communication receiver is configured to receive the control signal (the first commands and the second commands) from the mobile application installed on the mobile computing device 190 which is within the near field communication range. In an example, the first commands may represent the floor number button the user wants to press on the elevator panel. In another example, the second commands may define a first angle and a second angle which adjust the rotation of the dual arm. The microcontroller switches ON the motor to move the dual arm either in a first direction to press the first elevator button or in a second direction to press the second elevator button based on the first and second commands. On receiving the first commands, the microcontroller is configured to move the dual arm to a first operating position at a first angle. Upon receiving the second commands, the microcontroller is configured to move the dual arm to a second operating position at a second angle.

In some aspects, the user is presented with a selection screen on a mobile computing device 190, allowing the user to provide an option for pressing a floor number button for execution on the mobile application and on the elevator panel correspondingly. The user can use a multifunction button, trackwheel, or other navigation input methods or controls to highlight the selection or to use the numeric keypad to make the selection by numeric entry. For example, the user can use numeric keys on the mobile application to select the floor for which the user wants to press a button on the elevator panel and transmit the selected input as the first commands to the microcontroller.

In an exemplary aspect, the user may use either or both of the first non-contact device 110 (or the system 100) and the mobile computing device 190 to achieve the objectives of the present disclosure. The first non-contact device 110 is configured to record the movement of the fingers of the user for pressing the button of the elevator panel corresponding to the desired floor at which the user wants to go. The first non-contact device 110 is capable of communicating and synchronizing the recorded movements with the mobile application running on the mobile computing device. The first non-contact device 110 and the mobile computing device 190 may have communications capabilities that include but are not limited to, GPS, Bluetooth Low Energy (BLE), Wi-Fi, EDGE, 2G, 3G, 4G, LTE, a wired network, Bluetooth®, Near Field Communications (NFC), Infrared (IR), etc.). For example, and without limitation, the mobile computing device 190 may refer to a mobile device, a Personal Digital Assistant (PDA), a Global Positioning System (GPS) device, a wearable object, a smartwatch, a wearable sensor, a cellular telephone, a tablet, a netbook, a wireless terminal, a laptop computer, a wearable computing device or any other device. In an example, the mobile computing device 190 is a mobile system fabricated by Shenzhen Minew Technologies located at No. 8, Qinglong Road, Longhua District 518104, Shenzhen, China.

In a structural and operational aspect, the second non-contact device 150 and the third non-contact device 160 are substantially identical to the first non-contact device 110.

FIG. 1B-FIG. 1C illustrate an overall configuration of the first non-contact device 110.

FIG. 1B is a block diagram of the first non-contact device 110 (hereinafter interchangeably referred to as “the device 110”), according to one or more aspects of the present disclosure. The device 110 includes an input connector 112, the first proximity sensor 114, the second proximity sensor 116, a voltage regulator 118, the microcontroller 120, a battery 122, a first light emitting diode 124, a second light emitting diode 126, the motor 128, a buffer circuit 130, the motor shaft 132, the dual arm 134, the switch 136, the near field communication receiver 138, and an output connector 140.

The battery 122 is switchably connected to the motor. In an example, the battery 122 is a rechargeable battery. The battery 122 is configured to be recharged using a charging port (not shown in FIG.). The battery 122 is configured to provide suitable power to all components of the device 110. In an example, the battery 122 is selected from an exemplary group consisting of non-aqueous lithium-ion battery, polymer lithium-ion battery, and sodium sulfate battery.

The voltage regulator 118 is connected to the battery. The voltage regulator 118 is configured to maintain a constant DC voltage at the output irrespective of voltage fluctuations at the input and (or) variations in the load current. The voltage regulator 118 is selected from a group consisting of a switching regulator and a linear regulator.

The motor shaft 132 is connected to the motor 128. The motor shaft 132 is configured to rotate when the battery 122 is connected to the motor 128. The switch 136 is operatively connected to the motor 128.

The first proximity sensor 114 is configured to detect the first finger gesture and generate the first signal. The second proximity sensor 116 is configured to detect the second finger gesture and generate the second signal. As shown in FIG. 1B, the microcontroller 120 is connected to the switch 136, the first proximity sensor 114, the second proximity sensor 116, the first light emitting diode 124 and the second light emitting diode 126. The microcontroller 120 is configured to execute the program instructions to actuate the switch 136 to cause the motor 128 to move the dual arm 134. The dual arm 134 is configured to move in the first direction to press the first elevator button when the first signal is received. When the second signal is received, the dual arm 134 is configured to move in the second direction to press the second elevator button. In an example, the dual arm 134 is printed by 3D printing. In an example, after pushing the button, the dual arm 134 is configured to return to a rest position. In an example, in the rest position, the dual arm 134 extends in a plane normal to the elevator surface.

In an example, the microcontroller 120 is configured to switch ON the first light emitting diode 124 when the first signal is received and switch ON the second light emitting diode 126 when the second signal is received. The first light emitting diode 124 and the second light emitting diode 126 are configured to show which proximity sensor is activated. For example, if the microcontroller switches ON the first light emitting diode 124, the first proximity sensor 114 has detected the gesture of the user.

The near field communication receiver 138 is operatively connected to the microcontroller 120. The near field communication receiver 138 is configured to receive first commands from the mobile application installed on the mobile computing device 190 when within the near field communication range when the near field communication receiver 138 is switched ON by the microcontroller 120. In an example, the near field communication receiver 138 is an nRF52832 System-on-Chip (SoC) (fabricated by Nordic Semiconductor located at Otto Nielsens veg 12 7052 Trondheim, Norway). The microcontroller 120 is further configured to turn ON the switch 136 to actuate the motor 128 to rotate the dual arm in one of the first directions to press the first elevator button or the second direction to press the second elevator button based on the first commands.

The buffer circuit 130 is connected between the microcontroller 120 and the motor 128. The buffer circuit 130 is configured to store a usage count and increase the usage count when one of the first signal and the second signal are received by the microcontroller 120. In an example, the usage count may be used for analysis to detect which floors are visited by users of the elevator. Based on the analysis, the dedicated elevator can be assigned to the most visited floor such that the elevator traffic can be managed in an efficient way.

In an operative aspect, the microcontroller 120 is further configured to actuate the switch 136 to cause the motor 128 to rotate the motor shaft 132 such that the dual arm extends in the plane normal to the elevator surface when in a rest position. The button-pressing angle may not be hard-programmed. Therefore, correction in the angle can be performed through the mobile application 192 as and when needed after frequent use.

The dual arm 134 rotates from the rest position to a first operating position at a first angle in the range of -10 degrees to -30 degrees in the first direction when the first signal is received. The dual arm 134 rotates from the rest position to a second operating position at a second angle in the range of 10 degrees to 30 degrees in the second direction when the second signal is received.

The microcontroller 120 includes an electrical circuitry, a memory, and at least one processor. The memory is configured to store program instructions and a pair of floor numbers assigned to each of the first non-contact device 110, the second non-contact device 150 and the third non-contact device. In an example, the memory is a random access memory (“RAM”) for temporary storage of information and/or a read only memory (“ROM”) for permanent storage of information, and a mass storage device, such as a hard drive, diskette, or optical media storage device. In an example, the electrical circuitry is configured to employ preprocessing on the received data (signal) such as filtering and amplifying the received data. The at least one processor is configured to cooperate with the memory to fetch and execute computer-readable program instructions stored in the memory. According to an example of the present disclosure, the at least one processor may be implemented as one or more microcomputers, microcontrollers, digital signal processors, central processing units, state machines, logic circuitries, and/or any devices that manipulate signals based on operational instructions.

The microcontroller 120 is further configured to receive second commands from the mobile application. In an example, the second commands define the first angle and the second angle. The microcontroller 120 is configured to rotate the dual arm either to the first operating position at the first angle or rotate the dual arm 134 to the second operating position at the second angle, based on the second commands.

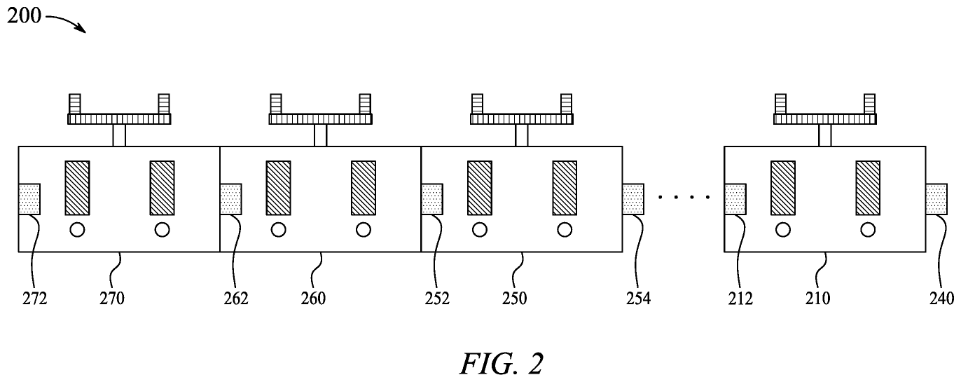

As shown in FIG. 1B-FIG. 1C and FIG. 2, to make a stackable configuration, the first non-contact device 110 is configured to connect with the second non-contact device 150 and the third non-contact device 160. To make the connection strong enough, dual in line connectors (the input connector and the output connector) are used to attach the first non-contact device 110 with the other non-contact devices. In an example, the input connector 112 is a female pin connector. In an example, the output connector 140 is a male pin connector. In an example, the housing 142 of the first non-contact device 110 is configured such that the non-contact device slides into another non-contact device easily with side guide slots.

In an operational aspect, each of the non-contact device (110, 150, 160) is configured to operate in the following ways:
1. By detecting a finger gesture using the first proximity sensor 114 or the second proximity sensor 116. For example, the first proximity sensor 114 detects a finger gesture for pressing the button (7) on the elevator panel and the second proximity sensor 116 detects a finger gesture for pressing the button (8) on the elevator panel. When the user comes into proximity of the first proximity sensor 114 and the second proximity sensor 116, the corresponding light emitting diode 124-126 coupled with the corresponding proximity sensor will turn ON and starts blinking. For example, the first light emitting diode 124 corresponding to the first proximity sensor is turned ON. This indicates to the user to move his finger over the button (7) on the elevator panel while the light emitting diode is blinking. Through the first proximity sensor 114, the user is thus able to give an instruction to the microcontroller 120 to press the button (7) on the elevator panel. In an example, the user is required to hover over the proximity sensor of the relevant floor for a predetermined length of time, e.g., 1.5 seconds such that the selected proximity sensor is able to determine whether the instruction is specific for it only. Each proximity sensor of each non-contact device is able to take instructions independently.
2. The non-contact system may be attached with the elevator panel in a permanent way, with for example, double sided tape or other non-permanent fastening means. In such cases, each of the non-contact devices (110, 150, 160) is configured to store a different floor number in the memory associated with that non-contact device (110, 150, 160). For example, the memory of the first non-contact device 110 stores floor numbers 1 and 2, the memory of the second non-contact device 150 stores floor numbers 3 and 4, the memory of the third non-contact device stores floor numbers 5 and 6. One of the non-contact devices (110, 150, 160) is configured to act as a master device and other connected non-contact devices act as the slave devices. In an example, the first non-contact device 110 acts as the master device and the other non-contact devices (150, 160) are slave devices. In a master-slave configuration, the first non-contact device 110 includes a pair of floor numbers stored in the memory for each of the first non-contact device 110, the second non-contact device 150 and the third non-contact device 160.

The microcontroller 120 is configured to determine whether the first commands matches one of the pair of floor numbers for the first non-contact device 110. When the first commands matches a floor number for the first non-contact device110, the microcontroller 120 actuates the switch to cause the motor 128 to move the dual arm 134 either in the first direction to press the first elevator button or the second direction to press the second elevator button. Further, the microcontroller 120 of the first non-contact device 110 is configured to use the second commands to adjust the angle of the dual arm 134. When the first commands match the floor number for the first non-contact device 110, the microcontroller 120 of the first non-contact device 110 is configured to increase the usage count of the first non-contact device by one.

When the first commands do not match a floor number for the first non-contact device 110, the microcontroller 120 determines whether the first commands match one of the floor numbers of the second non-contact device 150 and transmits the first commands to the second non-contact device 150. If the first commands received by the second non-contact device 150 match with one of the floor numbers of the second non-contact device 150, the microcontroller of the second non-contact device 150 is configured to increase its usage count by one.

When the first commands do not match a floor number for the first non-contact device 110, the microcontroller 120 of the first non-contact device 110 is configured to determine whether the first commands match one of the floor numbers of the third non-contact device 160 and transmit the first commands to the third non-contact device 160. If the first commands received by the third non-contact device 160 matches with one of the floor numbers of the third non-contact device 160, the microcontroller of the third non-contact device 160 is configured to increase its usage count by one.

FIG. 1C is an exemplary illustration of a top view of the non-contact device 110. As shown in FIG. 1C, the dual arm 134 is connected to the motor shaft 132 at a center of the arm. The dual arm has a first end 134a and a second end 134b. The dual arm 134 is configured to move with the motor shaft 132. As shown in FIG. 1C, the first non-contact device 110 includes a housing 142, a first protrusion 144, and a second protrusion 146. The first protrusion 144 is connected to the first end 134a of the dual arm 134. The first protrusion 144 extends perpendicularly from the first end 134a. The first protrusion 144 is configured to contact and/o depress the first elevator button. The second protrusion 146 is connected to the second end 134b of the dual arm 134. The second protrusion 146 extends perpendicularly from the second end 134b. The second protrusion 146 is configured to depress the second elevator button.

FIG. 2 illustrates an assembly 200 having a plurality of interconnected non-contact devices, according to aspects of the present disclosure. The second non-contact device 150 is identical to the first non-contact device 110. In an example, the first non-contact device 110 is configured as the master device and the second non-contact device 150 is configured as the slave device. The second non-contact device 150 is configured to connect with the first non-contact device 110. A connector plug of the second non-contact device 150 is connected to a connector socket (input connector) of the first non-contact device 110.

The third non-contact device 160 is identical to the first non-contact device 110. In an example, the first non-contact device 110 is configured to act as the master device and the third non-contact device 160 is configured to act as a slave device. The third non-contact device 160 is configured to connect in series with the first non-contact device 110 or with the second non-contact device 150. In an example, a connector socket of the third non-contact device 160 is connected to a connector plug (output connector) of the first non-contact device 110.

The near field communication receiver 138 of the first non-contact device 110 is configured to establish a connection with the other non-contact devices. When the first non-contact device 110 acts as the master device and the second non-contact device 150 and third first non-contact device 110 act as the slave devices, the near field communication receiver 138 of the first non-contact device 110 is turned ON and is operatively connected to receive the first commands and the second commands from the mobile application. Simultaneously, the near field communication receivers of the second non-contact device 150 and the third non-contact device 160 are turned OFF. In an example, the master device is configured to employ generic attribute (GATT) communication. In an example, the GATT communication defines a way that two Bluetooth Low Energy devices transfer data back and forth using concepts called services and characteristics. The master device employs the GATT communication for establishing communication with the slave devices for performing various operations such as setting and obtaining profiles of each slave device, updating the parameters associated with each slave device, transmitting customized commands to each slave device, and receiving response packets from each slave device.

As shown in FIG. 2, the plurality of interconnected non-contact devices has four (4) non-contact devices as an example for brevity. The plurality of interconnected non-contact devices includes the first non-contact device 210, the second non-contact device 250, the third non-contact device 260, and a fourth non-contact device 270. The configuration for assembly 200 is manufactured in a way that multiple non-contact devices can be attached to cover a multifloored elevator design.

In order to make a strong connection, dual in-line connectors (the input connector and the output connector) are used to attach the plurality of interconnected non-contact devices. In an example, the input connector 212 of the first non-contact device 210 is connected to an output connector 254 of the second non-contact device 250. An input connector 252 of the second non-contact device 250 is connected to an output connector (not shown in FIG. 2) of the third non-contact device 260. An input connector 262 of the third non-contact device 260 is connected to an output connector (not shown in FIG. 2) of the fourth non-contact device 270. In an example, an input connector 272 of the fourth non-contact device 270 is connected to an output connector (not shown in Figure) of the other non-contact device.

By adopting the stackable configuration through the assembly 200, the non-contact device can be universally attachable to the conventional elevator button layouts. In an example, the assembly 200 can be attached to the elevator panel using a double-sided tape or such attaching means. There is no need to modify or open the button panel. This results in an easy installation and good acceptability of the solution.

In another aspect, the assembly 200 can be attached to the outside surface of the elevator panel permanently using a screw-nut driving mechanism.

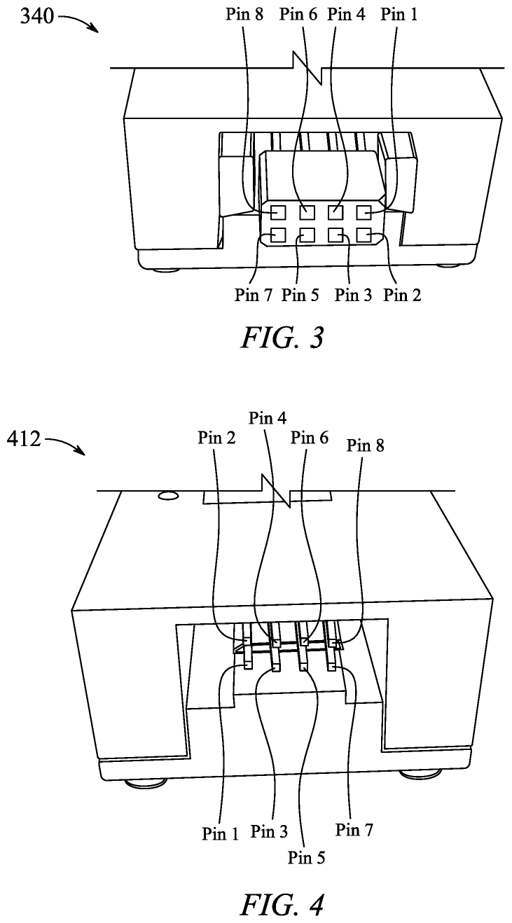

FIG. 3 is an exemplary illustration of an output connector panel 340 of the non-contact device, according to aspects of the present disclosure. The output connector panel 340 depicts eight (8) pins. The details of the pins are described in the Table 1. For example, Pin 3 represents a Universal asynchronous receiver-transmitter (UART) transmitting pin for the slave device. Pin 8 represents a UART receiving pin for the slave device. Pin 6 represents a data ready pin that the master device uses for sending the data to send to the slave devices.

TABLE 1
Detailed description of output connector pinouts

| Pin | Schematic | Pin | |
|---|---|---|---|
| Number | Connector name | Type | Details |
| 1 | GND | Power | Ground Connection |
| 2 | OUT_5 | Output | Set as slave - Sets the next |
| | | | connected block as slave |
| 3 | OUT_1 | Output | UART TX for Slave |
| 4 | OUT_4 | Input | Interrupt - Check if data is |
| | | | ready at slave |
| 5 | INT_OUT | — | Not Used - Reserved for |
| | | | future use |
| 6 | OUT_3 | Output | Data ready pin - Master has |
| | | | a data to send to slave |
| 7 | +VCC_5V_IN | Power | 5 V Power Out |
| 8 | OUT_2 | Input | UART RX for Slave |

FIG. 4 is an exemplary illustration of an input connector panel 412 of the non-contact device, according to aspects of the present disclosure. The input connector panel 412 depicts eight (8) pins. The details of the pins are described in the Table 2. Pin 1 represents a 5V power input. Pin 2 represents a Universal asynchronous receiver-transmitter (UART) transmitting pin for the master device. Pin 5 represents a UART receiving pin for the master device. Pin 6 represents a data ready pin that the master device use for sending a data to send to the slave device.

TABLE 2
Description of input connector pinouts

| Pin | Schematic | Pin | |
|---|---|---|---|
| Number | Connector name | Type | Details |
| 1 | +VCC_5V_IN | Power | 5 V Power Input |
| 2 | IN_2 | Output | UART TX for Master |
| 3 | INT_IN | — | Not Used - Reserved for |
| | | | future use |
| 4 | IN_3 | Input | Interrupt - Check if data is |
| | | | ready at Master |
| 5 | IN_1 | Input | UART RX for Master |
| 6 | IN_4 | Output | Data ready pin - Master has |
| | | | a data to send to slave |
| 7 | GND | Power | Ground Connection |
| 8 | IN_5 | Input | Set as Slave - if pin is high |
| | | | device will be set as master |

Based on the pin-configuration as described in Table 1 and Table 2, each non-contact device is configured to initialize as the master device or the slave device. The non-contact device determines if it is the master device or the slave device by a pin configuration between the input connector and the output connector. The controller of the non-contact device determines the status of Pin (pin 8, IN_5). If the pin is high, the non-contact device sets itself as a master. In the output connector, the pin 2 (OUT_5) is pulled out low, the master device is configured to make the connected device the slave device.

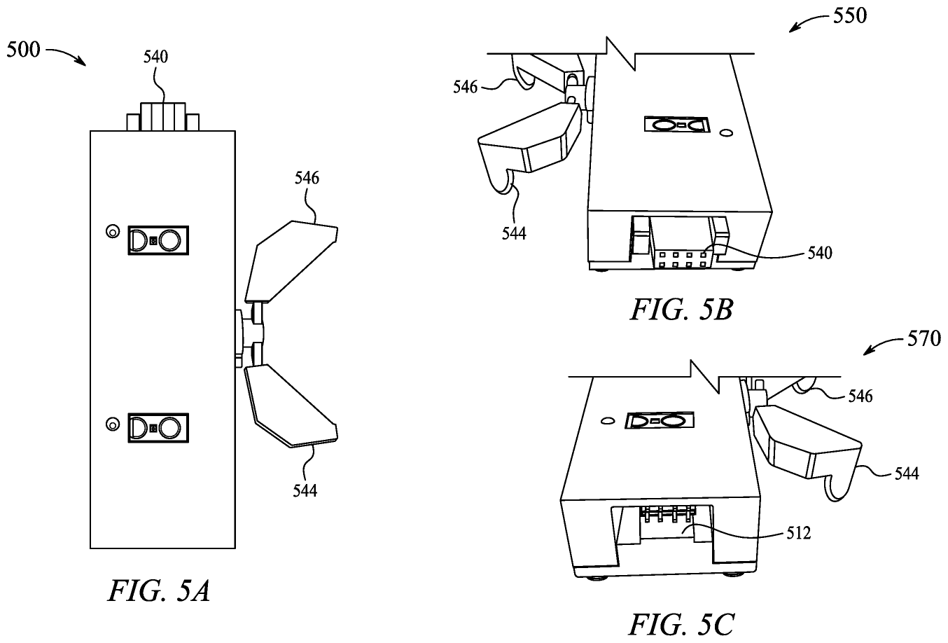

FIG. 5A-FIG. 5C represent various views of the first non-contact device 110.

FIG. 5A is an exemplary illustration 500 of the top view of the first non-contact device 110, according to aspects of the present disclosure. As shown in FIG. 5A-5C, the first non-contact device has the first end and the second end. A first protrusion 544 on the first end is configured to depress the first elevator button and a second protrusion 546 on the second end is configured to depress the second elevator button. The output connector 540 is configured to connect with the input connector 512 of another non-contact device.

FIG. 5B is an exemplary illustration of a side view 550 of the first non-contact device 110, according to aspects of the present disclosure.

FIG. 5C is another exemplary illustration 570 of another side view of the first non-contact device device 110, according to aspects of the present disclosure. The input connector 512 is configured to connect with the output connector 540 of another non-contact device, such as non-contact device 550.

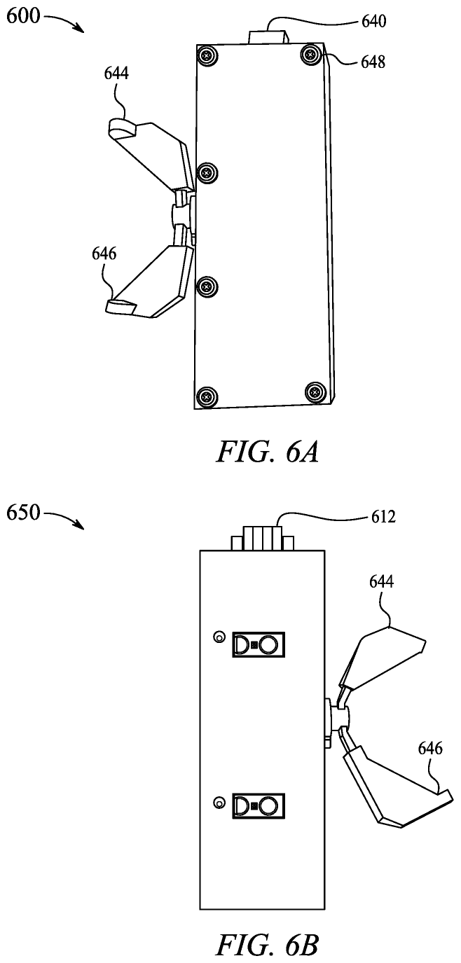

FIG. 6A is an exemplary illustration of a bottom view 600 of the first non-contact device 110, according to aspects of the present disclosure. As shown in FIG. 6A, the first non-contact device has the first protrusion 644, the second protrusion 646, and the output connector 640. In an example, a plurality of fasteners 648 is used for fastening the bottom surface of the housing with the top surface and 4 (four) sides of the housing. In an example, the plurality of fasteners are a plurality of screws. In an example, the plurality of fasteners may be a combination of any one or more of a bolt, a stud, a screw, a nut, and a tapping screw.

FIG. 6B is another exemplary illustration 650 of the top view of the first non-contact device, according to aspects of the present disclosure. As shown in FIG. 6B, the first protrusion 644 is positioned at the first angle in the range of −10 degrees to −30 degrees in the first direction. The second protrusion 646 is positioned at the second angle in the range of 10 degrees to 30 degrees in the second direction when the second signal is received. The input connector 612 is configured to connect with the output connector of another non-contact device.

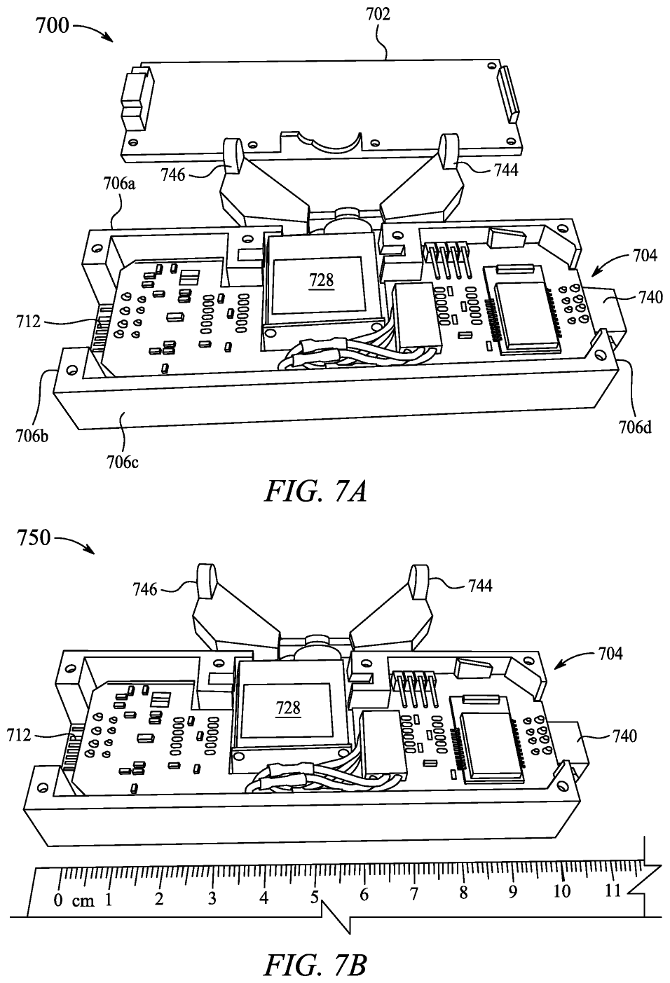

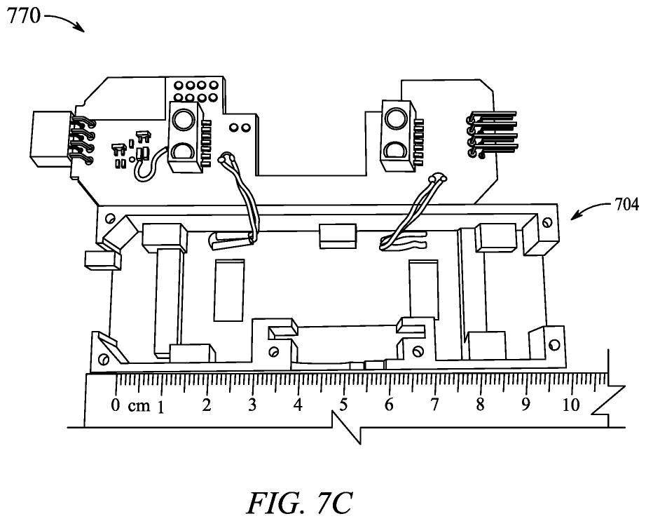

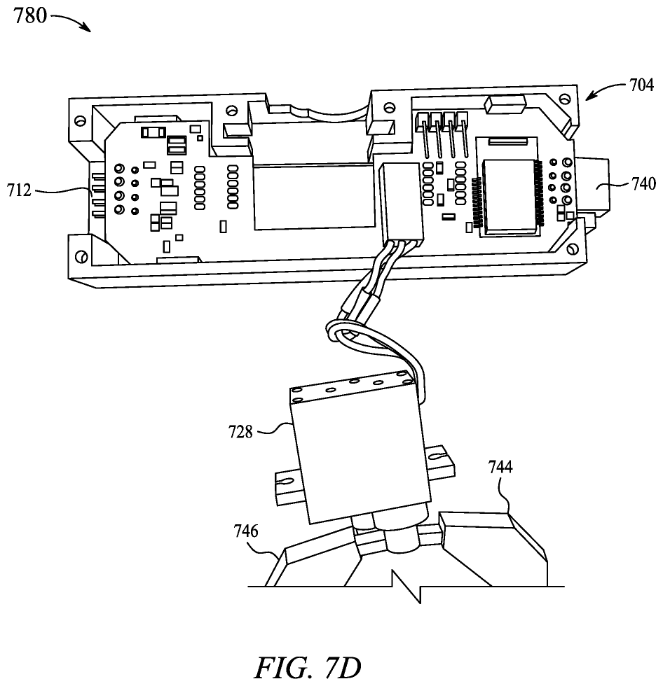

FIG. 7A illustrates a housing 700 of the first non-contact device 110 when a top surface 702 is removed, according to aspects of the present disclosure. The housing 700 includes the top surface 702, a bottom surface 704, a first side 706a, a second side 706b, a third side 706c, and a fourth side 706d. The second side 706b is perpendicular to the first side 706a. The third side 706c is opposite the first side 706a. The fourth side 706d is opposite the second side 706b. The top surface 702 is configured to hold the first proximity sensor 114, the second proximity sensor 116, the first light emitting diode 124 and the second light emitting diode 126. The housing 700 further includes an opening, a connector socket, a connector plug and an interior cavity. The connector socket (input connector 712) is located on the second side 706b. The connector plug (output connector 740) is located on the fourth side 706d. The opening for the motor shaft 132, is located at center of the first side 706a. The interior cavity is configured to hold the motor 728, the battery 122, the voltage regulator 118 and connection wirings.

As shown in FIG. 7A, the top surface 702 of the housing 700 of the non-contact device 110 is removable. An arrangement of the motor 728, the first protrusion 744, the second protrusion 746, the output connector 740, and the input connector 712 are shown in FIG. 7A when the top surface 702 is removed. In an example, the motor 728, the microcontroller (not shown), the output connector 740, and the input connector 712 are connected to a single printed circuit board (PCB).

FIG. 7B illustrates an assembled view 750 of all components placed inside the non-contact device 110 when the top surface 702 is removed, according to aspects of the present disclosure. Further, the size of the non-contact device 110 is shown in comparison with a scale. As shown in FIG.7B, the non-contact device 110 is quite small in size, preferably about 10 cm, therefore can adapt to the spacing of conventional elevator buttons.

FIG. 7C illustrates a bottom side 770 of the PCB when the PCB is removed from the housing 700, according to aspects of the present disclosure. As shown in FIG. 7C, the non-contact device 110 has a configuration that is easily replaceable, and also due to the simplicity of the non-contact device, it can be produced easily.

FIG. 7D illustrates an assembled view 780 of the motor connection and motor slot inside the non-contact device 110 when the top surface 702 is removed, according to aspects of the present disclosure. As shown in FIG. 7D, the motor 728 and the dual arm are easy to extract and replace, thereby providing an installation-friendly device.

Referring again to FIG. 7A-FIG. 7D, the complete non-contact device has a relatively simple construction, which still provides an effective coupling between the first non-contact device and the other non-contact devices.

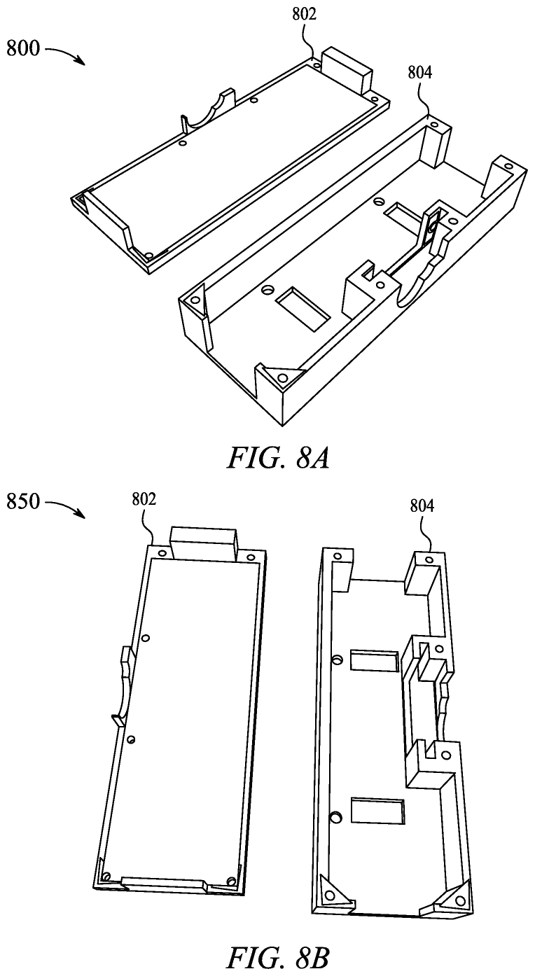

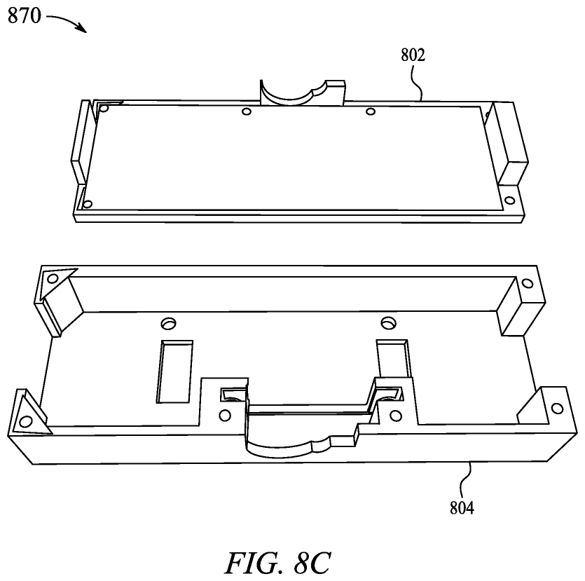

FIG. 8A illustrates a 3D model of the housing 800 of the non-contact device 110, according to aspects of the present disclosure. The top surface 802 and the bottom surface 804 are shown in FIG. 8A. The housing 800 of the non-contact device 110 is also designed so that it slides into another block easily with the side guide slots. In an example, the bottom surface 804 is a unitary member which is preferably constructed of a rigid and durable plastic material using conventional molding techniques.

FIG. 8B illustrates a 3D vertical cross sectional view 850 of the housing of the non-contact device, according to aspects of the present disclosure.

FIG. 8C illustrates a 3D horizontal cross sectional view 870 of the housing of the non-contact device, according to aspects of the present disclosure.

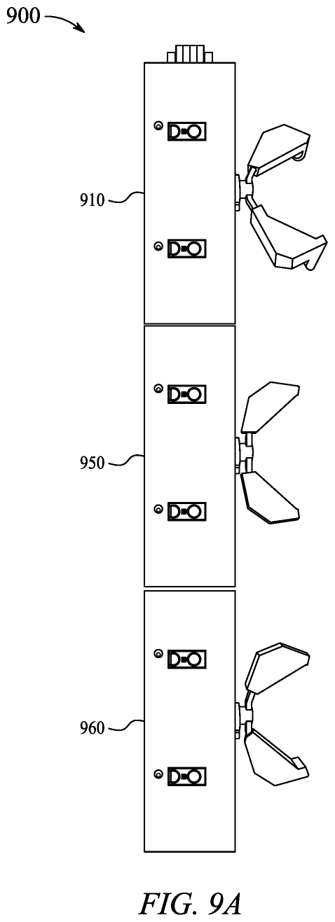

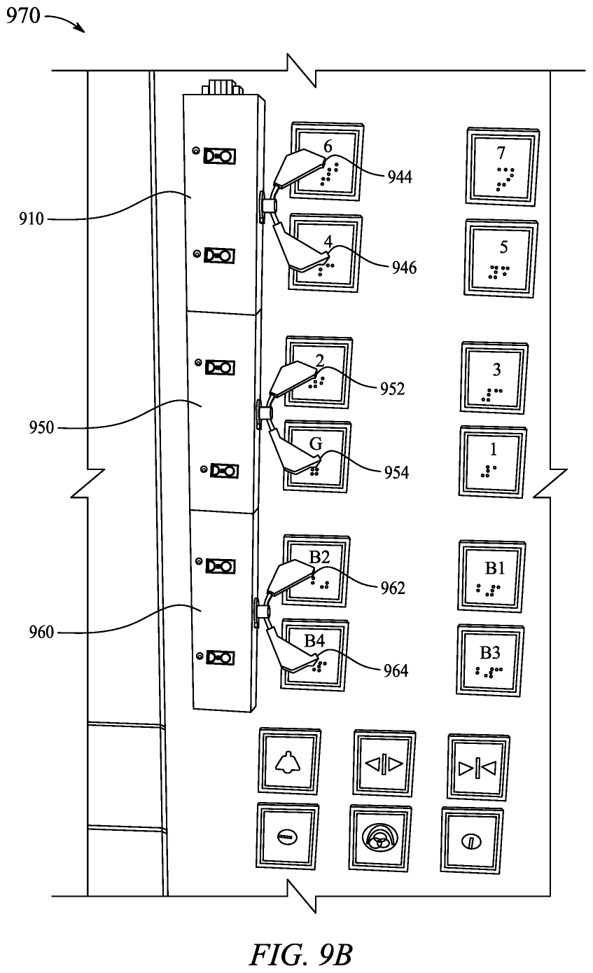

FIG. 9A is an exemplary illustration of the non-contact system 900 having three stacked non-contact devices (910, 950, and 960) connected to one another in series, according to aspects of the present disclosure. As shown in FIG. 9A, the three non-contact devices (910, 950, and 960) are stacked in series. In an example, the input connector (not shown) of the first non-contact device 910 is connected to an output connector (not shown) of the second non-contact device 950. An input connector (not shown) of the second non-contact device 950 is connected to an output connector (not shown in FIG.) of the third non-contact device 960.

FIG. 9B is an exemplary illustration of an installed system 970 having three stacked non-contact devices (910, 950, and 960), according to aspects of the present disclosure. The installed system 970 includes the first non-contact device 910, the second non-contact device 950 and the third non-contact device 960. As shown in FIG. 9B, each of the non-contact device (910, 950, and 960) has two protrusions: a first protrusion and a second protrusion. For example, the first non-contact device 910 has the first protrusion 944 which touches the surface of the elevator panel and the second protrusion 946 which is configured to press button four (4) on the elevator panel. The second non-contact device 950 has the first protrusion 952 and the second protrusion 954 which are configured to press buttons two (2) and ground (G) on the elevator panel. The third non-contact device 960 has the first protrusion 962 and the second protrusion 964 which are configured to press buttons B2 and B4 on the elevator panel, as shown in FIG. 9B.

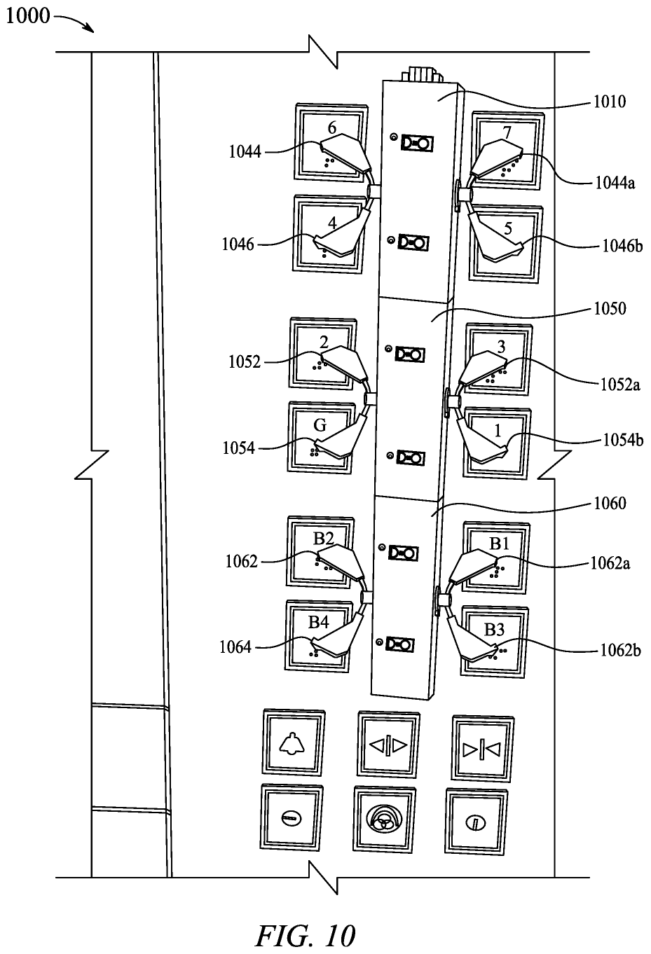

FIG. 10 is an exemplary illustration of an installed non-contact system 1000 having three non-contact devices, where each non-contact device has two dual arms and four protrusions, according to aspects of the present disclosure. The non-contact system 1000 is configured to be placed between the buttons on the elevator panel and pressed the buttons on both sides of the elevator panel. As shown in FIG. 10, each of the non-contact devices (1010, 1050, and 1060) has four protrusions for pressing four buttons on the elevator panel. For example, the first non-contact device 1010 has the first protrusion 1044, the second protrusion 1046, a third protrusion 1044a, and a fourth protrusion 1046b, which are configured to press buttons six (6) (by the first protrusion 1044), four (4) (by the second protrusion 1046), seven (7) (by the third protrusion 1044a) and five (5) (by the fourth protrusion 1046b) on the elevator panel. The second non-contact device 1050 has the first protrusion 1052, the second protrusion 1054, the third protrusion 1052a, and the fourth protrusion 1054b, which are configured to press buttons two (2) (by the first protrusion 1052), ground (G) (by the second protrusion 1054), three (3) (by the third protrusion 1052a) and one (1) (by the fourth protrusion 1054b) on the elevator panel. The third non-contact device 1060 has the first protrusion 1062, the second protrusion 1064, the third protrusion 1062a, and the fourth protrusion 1064b, which are configured to press buttons B2 (by the first protrusion 1062), B4 (by the second protrusion 1064), B1 (by the third protrusion 1062a) on the elevator panel, and B3 (by the third protrusion 1062b) on the elevator panel, as shown in FIG. 10.

The protrusions are not limited to the extended oval shape shown by protrusion 746 and protrusion 744 in FIG. 7A. The protrusions may be pointed, rounded, rectangular, angled with respect to the dual arm, be elongated and extend at an angle not equal to 90 degrees from the ends of the dual arm, and the like.

The non-contact device may be packaged in a kit which includes dual arms of different lengths, and a plurality of protrusions which can be connected to the dual arm ends as needed in order to install the non-contact device to cover elevator buttons having non-standard spacings. For example, an elevator with buttons spaced from center to center by about 15 cm may require a dual arm which is about 15 cm long, however, there may be only a choice of a 13 cm dual arm. A protrusion having a length of 1.5 cm which is angled at 30 degrees with respect to a perpendicular to the dual arm end can be attached, by a screw or push in fitting, to the dual arm end so as to tailor the non-contact device to the elevator button panel. Further, the dual arm may be removable and replaceable from the motor shaft to replace worn dual arms or switch the dual arm to a more workable size. For example, a selection of dual arms may include dual arms having a length of 5 cm, 7 cm, 9 cm, 10 cm, 13 cm and the like. Each arm of the dual arms may be manufactured in lengths ranging from 2 cm to 20 cm, and the selection of a length or lengths of dual arms in the kit may vary with geographic area in order to correspond to the spacings of the buttons on the elevator panels available from manufacturers in the geographic area.

Each of the non-contact devices includes a second shaft which moves a second dual-arm on the other side of the non-contact device. The non-contact device 1010 includes four proximity sensors and four LEDs. The non-contact device 1010 can be used when there are two rows of elevator buttons. In an example, the non-contact device 1010 includes a second buffer circuit for storing the usage count of the second shaft.

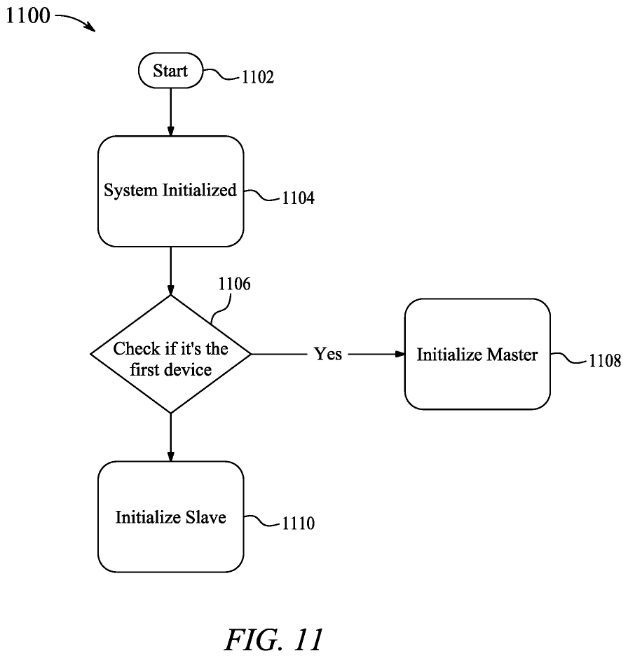

FIG. 11 is a flowchart 1100 of a device configuration selection process, according to aspects of the present disclosure.

Step 1102 includes starting (setting up) the non-contact system 100 having a plurality of non-contact devices for operating elevator buttons. In an example, an installer or user places the non-contact system along with the buttons of the elevator. In an example, the non-contact system 100 can be attached by with an elevator panel using a plurality of magnets. In an example, the plurality of magnets can be removed from the non-contact system 100 after the user actuates the button with the non-contact device. In an example, the non-contact system can include a double-sided sticky tape for providing a more permanent installation with the elevator panel.

Step 1104 includes initialization of the non-contact system 100. The first proximity sensor and the second proximity sensor of each non-contact device are powered by the battery when the microcontroller detects the finger gestures.

Step 1106 includes checking which non-contact device is the master device. The controller of each non-contact device checks the status of Pin (pin 8, IN_5).

Step 1108 includes an initialization of the non-contact device as the master device if the pin (pin 8, IN_5) is high. If in the output connector, the pin 2 (OUT_5) is pulled out low, the master device is configured to make the connected device as the slave device. During the initialization, the near field communication receiver is switched ON by the microcontroller of the master non-contact device.

Step 1110 includes an initialization of the non-contact device as the slave device. If in the output connector, the pin 2 (OUT_5) is pulled out low, the master device is configured to make the connected device as the slave device and the near field communication receiver of the slave device is OFF.

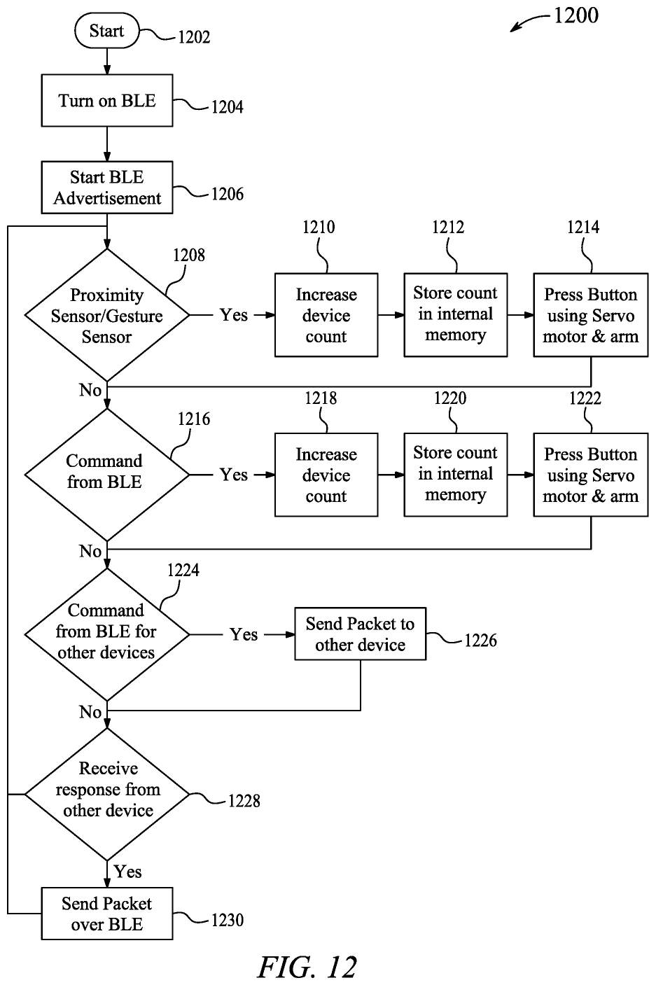

FIG. 12 is a flowchart 1200 of the master device process flow, according to aspects of the present disclosure.

Step 1202 includes starting (setting up) of the non-contact device (master device) for operating elevator buttons. Once the device is detected as the master device, it turns on the near field communication receiver. In an example, only the master device can turn-on its near field communication receiver while the slave devices turn off their near field communication receivers. In an example, the master device is configured to address each slave device by a count addressing. The master device is configured to communicate with all the slave devices. The master device is employed to configure the slave devices, e.g., to get the usage counter, and send a command to press a particular floor button. In an example, the usage count can be reset to zero if required.

Step 1204 includes initialization of the master device. During the initialization, the near field communication receiver is switched ON by the microcontroller of the master device.

Step 1206 includes advertising the Bluetooth low energy (BLE) broadcast messages by the near field communication receiver to those within a near field communication range.

Step 1208 includes activating the first proximity sensor or the second proximity sensor. The first proximity sensor detects a first finger gesture and generates a first signal. The second proximity sensor is configured to detect a second finger gesture and generates a second signal.

Step 1210 includes increasing a usage count by one when one of the first signal and the second signal are received by the microcontroller. In an example, the buffer circuit 130 is configured to store a usage count.

Step 1212 includes storing the usage count in the memory.

Step 1214 includes actuating the switch by the microcontroller to cause the motor to rotate the dual arm in a first direction to press the first elevator button when the first signal is received. The microcontroller actuates the switch to cause the motor to rotate the dual arm in a second direction to press the second elevator button when the second signal is received.

Step 1216 includes receiving BLE commands from the mobile application using the near field communication receiver. In an example, the microcontroller receives the first commands and the second commands from the mobile application 192 installed on the mobile computing device 190 within the near field communication range.

Step 1218 includes increasing the usage count by one when one of the first commands and the second commands are received by the microcontroller.

Step 1220 includes storing the usage count in the memory.

Step 1222 includes actuating the switch by the microcontroller to cause the motor to rotate the dual arm. The microcontroller is further configured to switch the motor to rotate the dual arm in one of the first direction to press the first elevator button and the second direction to press the second elevator button based on the first commands. The microcontroller is configured to switch the motor to rotate the dual arm either in the first operating position at the first angle and rotate the dual arm to the second operating position at the second angle, based on the second commands.

Step 1224 includes receiving BLE commands from the mobile application 192 using the near field communication receiver for other non-contact devices. After receiving the commands from the mobile application, the master is configured to check whether the commands are received for the other non-contact devices or not. If the commands are intended for the master, the steps 1216-1222 will be performed.

When the command is received by the master device from the mobile application 192, the master device checks if the command is for the master device or for the slave device. If the command is for the master device, the master device processes the received command and replies to the mobile application 192. If this is not the case, the master device will send out the command to the next slave device which is attached directly to the master via Universal Asynchronous Receiver/Transmitter (UART) communication. Structure of the UART communication protocol has been detailed through the following two examples in Table 3 and Table 4.

TABLE 3
Structure of UART communication for “Press button” evet

| Packet | Pre- | CMD | | | | Post- |
|---|---|---|---|---|---|---|
| format | amble | for | Counter | CMD | Param1 | amble |
| Press button | 0 × 24 | 0 × 02 | 0 × 01 | 0 × 01 | 0 × 02 | 0 × 0 D |

TABLE 4
Structure of UART communication for “Set angle” event

| Packet | Pre- | CMD | | | | | | Post- |
|---|---|---|---|---|---|---|---|---|
| format | amble | for | Counter | CMD | Param1 | Param2 | Param3 | amble |
| Set | 0 × 24 | 0 × 04 | 0 × 01 | 0 × 21 | 0 × 5 A | 0 × 1E | 0 × 1E | 0 × 0 D |
| angle | | | | | | | | |

Step 1226 includes transmitting the BLE commands to a slave non-contact device.

Step 1228 includes receiving the response from the slave non-contact device and checking whether the commands belonged to the slave non-contact device or not.

Step 1230 includes transmitting the BLE commands to another slave non-contact device. If the commands do not belong to the previous non-contact device, the microcontroller of the master device will transmit the BLE commands to another slave non-contact device.

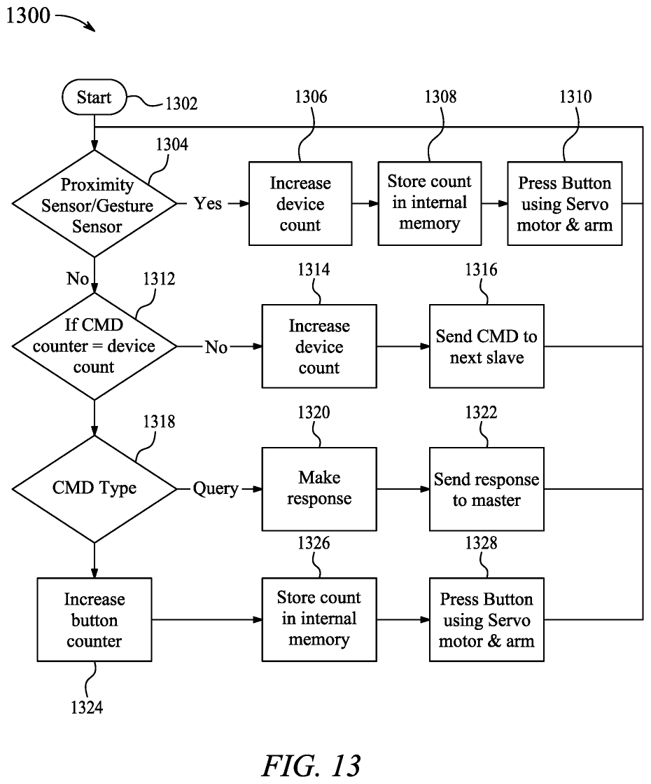

FIG. 13 is a flowchart 1300 of the slave device process flow, according to aspects of the present disclosure.

Step 1302 includes starting (setting up) of the non-contact device (slave device) for operating elevator buttons.

Step 1304 includes activating the first proximity sensor and the second proximity sensor. The first proximity sensor detects the first finger gesture and generates the first signal. The second proximity sensor configured to detect the second finger gesture and generate the second signal.

Step 1306 includes increasing a usage count by one when one of the first signal and the second signal are received by the microcontroller. In an example, the buffer circuit 130 is configured to store a usage count.

Step 1308 includes storing the usage count in the memory or in the buffer circuit.

Step 1310 includes actuating the switch by the microcontroller to cause the motor to rotate the dual arm in a first direction to press the first elevator button when the first signal is received. The microcontroller actuates the switch to cause the motor to rotate the dual arm in a second direction to press the second elevator button when the second signal is received.

Step 1312 includes checking whether the command counter is equal to the current usage count. Every time a packet is received by the slave device, the slave device checks out the current usage count and command counter. If both match, the slave device processes the packets information. If the current usage count and command counter does not match, the slave device increases the usage count and passes the packet to another slave device. This process goes on until the desired device is reached.

Step 1314 includes increasing the count by one if the command counter is not equal to the current usage count.

Step 1316 includes transmitting the commands to the next non-contact device.

Step 1318 includes checking type of the commands and transmitting a query to the slave device.

Step 1320 includes making a response to the query. If a command is received that needs a response, the same packet-passing mechanism is followed until the packet reaches the master device. In an example, the proximity sensors also work the same way as the master device.

Step 1322 includes transmitting the query response to the master device.

Step 1324 includes increasing the button counter.

Step 1326 includes storing the usage count in the memory.

Step 1328 includes actuating the switch by the microcontroller to cause the motor to rotate the dual arm in a first direction to press the first elevator button when the first signal is received. The microcontroller actuates the switch to cause the motor to rotate the dual arm in a second direction to press the second elevator button when the second signal is received.

The stackable, non-contact device for operating elevator buttons of the present disclosure may incorporate one or more, and preferably all of the following features:
1. A stackable approach for greater freedom in the design and configuration of the device with respect to a single or multiple elevator button controls.
2. A non-intrusive device solution which can be installed to any/most of elevator button panels with different configurations.
3. A master and slave approach, enabled onto the device where one device serves as a master, which controls all other stackable devices.
4. A seamless communication method between the devices for interoperable operation of the elevator system.
5. Improving traditional elevator controls with advanced operational capabilities of communication using Bluetooth low energy without significant hardware modification.
6. Automatic storage of the usage information for each button panel for usage analytics.
7. Configurable projection of the moving angle of the motor for seamless button panel operation.

In an example, the stackable, non-contact device 1010 may be employed in various applications such as in autonomous delivery vehicle/robot dog or indoor bot to seamlessly use the existing elevators via the near field communication receiver.

In an example, the non-contact device 110 is configured to add a custom feature to the existing elevator mobile application to enable personalized elevator callouts on multiple floors through proximity-based automatic detection and sensing.

A first embodiment is illustrated with respect to FIG. 1-FIG. 13. The first embodiment describes the non-contact system 100 for operating elevator buttons. The non-contact system 100 includes a first non-contact device 110. The first non-contact device 110 includes a motor 128, a battery 122 switchably connected to the motor 128, a voltage regulator 118 connected to the battery 122, a motor shaft 132 connected to the motor 128, wherein the motor shaft 132 is configured to rotate when the battery 122 is connected to the motor 128, a dual arm 134 connected to the motor shaft 132 at a center of the arm 134, wherein the dual arm 134 has a first end 134a and a second end 134b, wherein the dual arm 134 is configured to rotate with the motor shaft 132, a first protrusion 144 connected to the first end 134a, wherein the first protrusion 144 extends perpendicularly from the first end 134a, wherein the first protrusion 144 is configured to depress a first elevator button, a second protrusion 146 connected to the second end 134b, wherein the second protrusion 146 extends perpendicularly from the second end 134b, wherein the second protrusion 146 is configured to depress a second elevator button, a switch 136 operatively connected to the motor 128, a first proximity sensor 114 configured to detect a first finger gesture and generate a first signal, a second proximity sensor 116 configured to detect a second finger gesture and generate a second signal, a microcontroller 120 connected to the switch, the first proximity sensor and the second proximity sensor, wherein the microcontroller 120 includes an electrical circuitry, a memory including program instructions and at least one processor configured to execute the program instructions to: actuate the switch 136 to cause the motor 128 to rotate the dual arm 134 in a first direction to press the first elevator button when the first signal is received, and actuate the switch 136 to cause the motor 128 to rotate the dual arm 134 in a second direction to press the second elevator button when the second signal is received, wherein the second direction is rotationally opposite the first direction.

In an aspect, the first non-contact device 110 includes a first light emitting diode 124, and a second light emitting diode 126, wherein the microcontroller 120 is connected to the first light emitting diode 124 and the second light emitting diode 126, wherein the microcontroller 120 is configured to switch ON the first light emitting diode 124 when the first signal is received and switch ON the second light emitting diode 126 when the second signal is received.

In an aspect, the first non-contact device 110 includes a housing 700 including a top surface 702, a bottom surface 704, a first side 706a, a second side 706b perpendicular to the first side 706a, a third side 706c opposite the first side 706a, and a fourth side 706d opposite the second side 706b, wherein the top surface 702 is configured to hold the first proximity sensor 114, the second proximity sensor 116, the first light emitting diode 124 and the second light emitting diode 126. The first non-contact device 110 includes a connector socket located in the second side 706b, a connector plug located in the fourth side 706d, an opening for the motor shaft 132 located in a center of the first side 706a, and an interior cavity configured to hold the motor 128, battery 122, the voltage regulator 118 and connection wiring.

In an aspect, the first non-contact device 110 includes a near field communication receiver operatively connected to the microcontroller 120, wherein the near field communication receiver is configured to receive first commands from a mobile application installed on a mobile computing device 190 within a near field communication range when the near field communication receiver is switched ON by the microcontroller 120, and the microcontroller 120 is further configured to switch on the motor 128 to rotate the dual arm 134 in one of the first direction to press the first elevator button and the second direction to press the second elevator button based on the first commands.

In an aspect, the microcontroller 120 is further configured to actuate the switch 136 to cause the motor 128 to rotate the motor shaft 132 such that: the dual arm 134 extends in a plane normal to the elevator surface when in a rest position; the dual arm 134 rotates from the rest position to a first operating position at a first angle in the range of −10 degrees to −30 degrees in the first direction when the first signal is received; and the dual arm 134 rotates from the rest position to a second operating position at a second angle in the range of 10 degrees to 30 degrees in the second direction when the second signal is received.

In an aspect, the microcontroller 120 is further configured to: receive second commands from the mobile application, wherein the second commands define the first angle and the second angle; and one of rotate the dual arm 134 to the first operating position at the first angle and rotate the dual arm 134 to the second operating position at the second angle, based on the second commands.

In an aspect, the first non-contact device 110 includes a buffer circuit 130 connected between the microcontroller 120 and the motor 128, wherein the buffer circuit 130 is configured to store a usage count and increase the usage count when one of the first signal and the second signal are received by the microcontroller 120.

In an aspect, the non-contact system 100 includes a second non-contact device 150 identical to the first non-contact device 110, wherein the first non-contact device 110 is configured as a master device and the second non-contact device 150 is configured as a slave device, wherein the connector plug of the second non-contact device 150 is connected to the connector socket of the first non-contact port.

In an aspect, the non-contact system 100 includes a third non-contact device 160 identical to the first non-contact device 110, wherein the first non-contact device 110 is configured as a master device and the third non-contact device 160 is configured as a slave device, wherein the connector socket of the third non-contact device 160 is connected to the connector plug of the first non-contact port.

In an aspect, the near field communication receiver of the first non-contact device 110 is turned ON and is operatively connected to receive the first commands and the second commands from the mobile application 192, and the near field communication receivers of the second non-contact device 150 and the third non-contact device 160 are turned OFF.

In an aspect, the first non-contact device 110 includes a pair of floor numbers stored in the memory for each of the first non-contact device 110, the second non-contact device 150 and the third non-contact device, wherein the microcontroller 120 is configured to: determine whether the first commands match one of the pair of floor numbers for the first non-contact device 110. When the first commands match a floor number for the first non-contact device 110, the microcontroller 120 is configured to actuate the switch 136 to cause the motor 128 to rotate the dual arm 134 in one of a first direction to press the first elevator button and a second direction to press the second elevator button. When the first commands do not match a floor number for the first non-contact device 110, the microcontroller 120 is configured to determine whether the first commands match one of the floor numbers of the second non-contact device 150 and transmit the first commands to the second non-contact device 150. When the first commands do not match a floor number for the first non-contact device 110 or a floor number of the second non-contact device 150, the microcontroller 120 is configured to determine whether the first commands match one of the floor numbers of the third non-contact device 160 and transmit the first commands to the third non-contact device.

In an aspect, when the first commands match a floor number for the first non-contact device 110, the microcontroller 120 of the first non-contact device 110 is configured to use the second commands to adjust the angle of the dual arm 134. When the first commands do not match a floor number for the first non-contact device 110, the microcontroller 120 of the first non-contact device 110 is configured to determine whether the first commands match one of the floor numbers of the second non-contact device 150 and transmit the second commands to the second non-contact device 150. When the first commands do not match a floor number for the first non-contact device 110 or a floor number of the second non-contact device 150, the microcontroller 120 of the first non-contact device 110 is configured to determine whether the first commands match one of the floor numbers of the third non-contact device 160 and transmit the second commands to the third non-contact device.

In an aspect, when the first commands match a floor number for the first non-contact device 110, the microcontroller 120 of the first non-contact device 110 is configured to increase the usage count of the first non-contact device 110 by one. When the first commands do not match a floor number for the first non-contact device 110, the microcontroller 120 of the first non-contact device 110 is configured to determine whether the first commands match one of the floor numbers of the second non-contact device 150 and transmit the first commands to the second non-contact device 150, wherein the microcontroller 120 of the second non-contact device 150 is configured to increase its usage count by one. When the first commands do not match a floor number for the first non-contact device 110, the microcontroller 120 of the first non-contact device 110 is configured to determine whether the first commands match one of the floor numbers of the third non-contact device 160 and transmit the first commands to the third non-contact device, wherein the microcontroller 120 of the third non-contact device 160 is configured to increase its usage count by one.

A second embodiment is illustrated with respect to FIG. 1-FIG. 13. The second embodiment describes a stackable master-slave non-contact system 100 for operating elevator buttons. The stackable master-slave non-contact system 100 includes a plurality of non-contact devices (110, 150, 160). Each non-contact device (110, 150, 160) includes a motor 128, a battery 122 switchably connected to the motor 128, a voltage regulator 118 connected to the battery 122, a motor shaft 132 connected to the motor 128, wherein the motor shaft 132 is configured to rotate when the battery 122 is connected to the motor 128, a dual arm 134 connected to the motor shaft 132 at a center of the arm, wherein the dual arm 134 has a first end 134a and a second end 134b, wherein the dual arm 134 is configured to rotate with the motor shaft, a first protrusion 144 connected to the first end 134a, wherein the first protrusion 144 extends perpendicularly from the first end 134a, wherein the first protrusion 144 is configured to depress a first elevator button, a second protrusion 146 connected to the second end 134b, wherein the second protrusion 146 extends perpendicularly from the second end 134b, wherein the second protrusion 146 is configured to depress a second elevator button, a switch 136 operatively connected to the motor 128, a first proximity sensor 114 configured to detect a first finger gesture and generate a first signal, a second proximity sensor 116 configured to detect a second finger gesture and generate a second signal, a microcontroller 120 connected to the switch 136, the first proximity sensor and the second proximity sensor, wherein the microcontroller 120 includes an electrical circuitry, a memory including program instructions and at least one processor configured to execute the program instructions to: actuate the switch 136 to cause the motor 128 to rotate the dual arm 134 in a first direction to press the first elevator button when the first signal is received, and actuate the switch 136 to cause the motor 128 to rotate the dual arm 134 in a second direction to press the second elevator button when the second signal is received, wherein the second direction is rotationally opposite the first direction. The system further includes a first light emitting diode 124, and a second light emitting diode 126, wherein the microcontroller 120 is connected to the first light emitting diode 124 and the second light emitting diode 126, wherein the microcontroller 120 is configured to switch ON the first light emitting diode 124 when the first signal is received and switch ON the second light emitting diode 126 when the second signal is received. The system 100 further includes a near field communication receiver 138 operatively connected to the microcontroller 120, wherein the near field communication receiver 138 is configured to receive first commands from a mobile application installed on a mobile computing device 190 within a near field communication range when the near field communication receiver 138 is turned ON, wherein the microcontroller 120 is further configured to switch the motor 128 to rotate the dual arm 134 in one of the first direction to press the first elevator button and the second direction to press the second elevator button based on the first commands. The system further includes a buffer circuit 130 connected between the microcontroller 120 and the motor 128, wherein the buffer circuit 130 is configured to store a usage count and increase the usage count when one of the first signal and the second signal are received by the microcontroller 120.

In an aspect, the first non-contact device 110 is configured as a master device having the near field communication device turned ON, and the remaining plurality of non-contact devices are configured as slave devices having the near field communication device turned OFF.

In an aspect, each non-contact device is surrounded by a housing including a top surface, a bottom surface, a first side, a second side perpendicular to the first side, a third side opposite the first side, and a fourth side opposite the second side, wherein the top surface is configured to hold the first proximity sensor, the second proximity sensor, the first light emitting diode 124 and the second light emitting diode 126, a connector socket located in the second side, a connector plug located in the fourth side, an opening for the motor shaft 132 located in a center of the first side, and an interior cavity configured to hold the motor 128, battery 122, the voltage regulator 118 and connection wiring.

In an aspect, each slave device is connected by one of the connector socket and the connector plug to one of the connector plug and the connector socket respectively of the master device, or each slave device is connected by one of the connector socket and the connector plug to one of the connector plug and the connector socket respectively of an adjacent slave device.

In an aspect, the stackable master-slave non-contact system 100 includes a pair of floor numbers stored in the memory of the master device for each of the master device and the slave devices, wherein the near field communication receiver 138 of the master device is configured to receive first commands and second commands from a mobile application installed on a mobile computing device 190 within a near field communication range when the near field communication receiver 138 is switched ON by the microcontroller 120, wherein the microcontroller 120 is configured to: determine whether the first commands match one of the pair of floor numbers for the master device; when the first commands match a floor number for the master device, actuate the switch 136 to cause the motor 128 to rotate the dual arm 134 to the first operating position at the first angle to press the first elevator button and rotate the dual arm 134 to the second operating position at the second angle to press the second elevator button based on the first commands and the second commands; when the first commands do not match a floor number for the master device, determine whether the first commands match one of the floor numbers of a slave device connected to the connector socket and transmit the first commands and the second commands to the slave device connected to the connector socket; when the first commands do not match a floor number for the master device or a floor number of the slave device connected to the connector socket, determine whether the first commands match one of the floor numbers of the slave device connected to the connector plug and transmit the first commands and the second commands to the slave device connected to the connector plug; when the first commands do not match one of a floor number for the master device, a floor number of the slave device connected to the connector plug and a floor number of the slave device connected to the connector socket, determine which one of a slave device connected in series with the slave device connected to the connector plug and a slave device connected in series with the slave device connected to the connector socket has a floor number which matches the first commands, and transmit the first commands and the second commands to the slave device which has a floor number which matches the first commands; and wherein the microcontroller 120 of each of the plurality of non-contact devices is configured to adjust an angle of the dual arm 134 to a first angle and a second angle based on the second commands.

In an aspect, the buffer circuit 130 of each of the plurality of non-contact devices is configured to increase its usage count by one when the first commands are received.

A third embodiment is illustrated with respect to FIG. 1-FIG. 13. The third embodiment describes a method for using a stackable master-slave non-contact system 100 for operating elevator buttons. The method includes operatively stacking a plurality of non-contact devices (110, 150, 160) onto the surface of an elevator control panel so that teach of the plurality of non-contact devices is adjacent to a pair of elevator buttons. For each of the plurality of non-contact devices, the method includes monitoring, by a microcontroller 120 of the non-contact device, a first proximity sensor 114 for a first signal and a second proximity sensor 116 for a second signal. The method includes receiving, by the microcontroller 120 one of the first signal and the second signal. The method includes updating, by a buffer circuit 130 connected to the microcontroller 120, a usage count of a buffer circuit upon receiving one of the first signal and the second signal. The method includes actuating, by the microcontroller 120, a motor configured to rotate a dual arm 134 connected to the motor in one of a first rotational direction such that a first protrusion 144 presses a first elevator button based on the first signal and in a second rotational direction such that a second protrusion 146 presses a second elevator button based on the second signal. The method includes switching ON a first light emitting diode 124 adjacent to the first proximity sensor upon receiving the first signal and switching ON a second light emitting diode 126 adjacent to the second proximity sensor upon receiving the second signal.

In an aspect, the method includes connecting the plurality of non-contact devices (110, 150, 160) together in a series configuration that matches a pattern of the elevator buttons. The method includes designating one of the non-contact devices as a master device. The method further includes turning ON a near field communication receiver 138 of the master device. The method further includes connecting the near field communication receiver 138 with a mobile application installed on a mobile computing device 190 within a near field communication range. The method further includes receiving, from the mobile application, a first set of commands for pressing an elevator button for a selected floor. The method further includes receiving, from the mobile application, a second set of commands for adjusting an angle of a dual arm 134 having a first protrusion 144 configured to press a first elevator button and a second protrusion configured to press one of a second elevator button adjacent the first elevator button for the selected floor. The method further includes updating the usage counter based on receiving the first set of commands. The method further includes determining if the selected floor matches a floor number stored in a memory of the master device. The method further includes when the selected floor matches the floor number stored in the memory, actuating the motor to rotate the dual arm 134 to press one of the first elevator button and the second elevator button based on the floor number. When the selected floor does not match the floor number stored in the memory, the method further includes transmitting the first commands and the second commands to each slave device in the series connection of slave devices, until the microcontroller 120 of one of the slave devices, determines there is a match to a floor number stored in its memory, and actuating the motor of the one of the slave devices to rotate the dual arm 134 to press one of the first elevator button and the second elevator button based on the floor number.

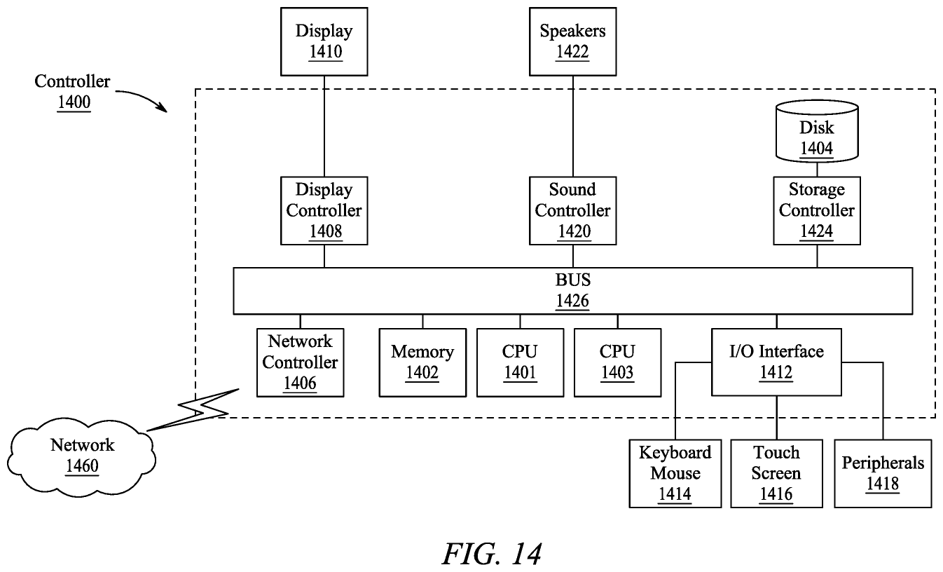

Next, further details of the hardware description of the computing environment of FIG. 1 according to exemplary embodiments is described with reference to FIG. 14.

In FIG. 14, a controller 1400 is described as representative of the non-contact system 100 of FIG. 1 in which the microcontroller 120 is a computing device which includes a CPU 1401 which performs the processes described above/below. FIG. 14 is an illustration of a non-limiting example of details of computing hardware used in the computing system, according to exemplary aspects of the present disclosure. In FIG. 14, a controller 1400 is described which is a computing device (that includes the microcontroller 120) and includes a CPU 1401 which performs the processes described above/below. The process data and instructions may be stored in memory 1402. These processes and instructions may also be stored on a storage medium disk 1404 such as a hard drive (HDD) or portable storage medium or may be stored remotely.

Further, the claims are not limited by the form of the computer-readable media on which the instructions of the inventive process are stored. For example, the instructions may be stored on CDs, DVDs, in FLASH memory, RAM, ROM, PROM, EPROM, EEPROM, hard disk or any other information processing device with which the computing device communicates, such as a server or computer.

Further, the claims may be provided as a utility application, background daemon, or component of an operating system, or combination thereof, executing in conjunction with CPU 1401, 1403 and an operating system such as Microsoft Windows 7, UNIX, Solaris, LINUX, Apple MAC-OS and other systems known to those skilled in the art.

The hardware elements in order to achieve the computing device may be realized by various circuitry elements, known to those skilled in the art. For example, CPU 1401 or CPU 1403 may be a Xenon or Core processor from Intel of America or an Opteron processor from AMD of America, or may be other processor types that would be recognized by one of ordinary skill in the art. Alternatively, the CPU 1401, 1403 may be implemented on an FPGA, ASIC, PLD or using discrete logic circuits, as one of the ordinary skill in the art would recognize. Further, CPU 1401, 1403 may be implemented as multiple processors cooperatively working in parallel to perform the instructions of the inventive processes described above.

The computing device in FIG. 14 also includes a network controller 1406, such as an Intel Ethernet PRO network interface card from Intel Corporation of America, for interfacing with network 1460. As can be appreciated, the network 1460 can be a public network, such as the Internet, or a private network such as an LAN or WAN network, or any combination thereof and can also include PSTN or ISDN sub-networks. The network 1460 can also be wired, such as an Ethernet network, or can be wireless such as a cellular network including EDGE, 3G and 4G wireless cellular systems. The wireless network can also be WiFi, Bluetooth, or any other wireless form of communication that is known.

The computing device further includes a display controller 1408, such as a NVIDIA GeForce GTX or Quadro graphics adaptor from NVIDIA Corporation of America for interfacing with display 1410, such as a Hewlett Packard HPL2445w LCD monitor. A general purpose I/O interface 1412 interfaces with a keyboard and/or mouse 1414 as well as a touch screen panel 1416 on or separate from display 1410. General purpose I/O interface also connects to a variety of peripherals 1418 including printers and scanners, such as an OfficeJet or DeskJet from Hewlett Packard.

A sound controller 1420 is also provided in the computing device such as Sound Blaster X-Fi Titanium from Creative, to interface with speakers/microphone 1422 thereby providing sounds and/or music.

The general-purpose storage controller 1424 connects the storage medium disk 1404 with communication bus 1426, which may be an ISA, EISA, VESA, PCI, or similar, for interconnecting all of the components of the computing device. A description of the general features and functionality of the display 1410, keyboard and/or mouse 1414, as well as the display controller 1408, storage controller 1424, network controller 1406, sound controller 1420, and general purpose I/O interface 1412 is omitted herein for brevity as these features are known.

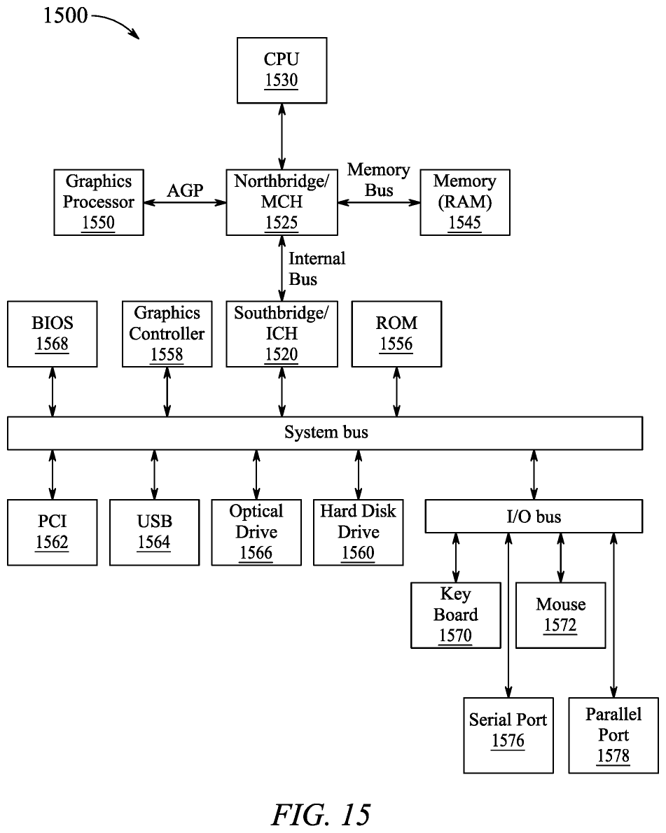

The exemplary circuit elements described in the context of the present disclosure may be replaced with other elements and structured differently than the examples provided herein. Moreover, circuitry configured to perform features described herein may be implemented in multiple circuit units (e.g., chips), or the features may be combined in circuitry on a single chipset, as shown on FIG. 15.

FIG. 15 shows a schematic diagram of a data processing system 1500 used within the computing system, according to exemplary aspects of the present disclosure. The data processing system 1500 is an example of a computer in which code or instructions implementing the processes of the illustrative aspects of the present disclosure may be located.

In FIG. 15, data processing system 1580 employs a hub architecture including a north bridge and memory controller hub (NB/MCH) 1525 and a south bridge and input/output (I/O) controller hub (SB/ICH) 1520. The central processing unit (CPU) 1530 is connected to NB/MCH 1525. The NB/MCH 1525 also connects to the memory 1545 via a memory bus, and connects to the graphics processor 1550 via an accelerated graphics port (AGP). The NB/MCH 1525 also connects to the SB/ICH 1520 via an internal bus (e.g., a unified media interface or a direct media interface). The CPU Processing unit 1530 may contain one or more processors and even may be implemented using one or more heterogeneous processor systems.

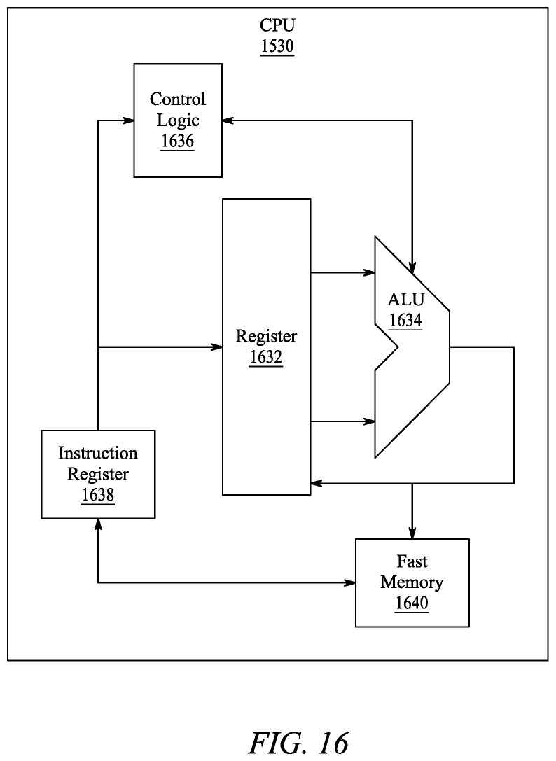

For example, FIG. 16 shows one aspects of the present disclosure of CPU 1530. In one aspects of the present disclosure, the instruction register 1638 retrieves instructions from the fast memory 1640. At least part of these instructions is fetched from the instruction register 1638 by the control logic 1636 and interpreted according to the instruction set architecture of the CPU 1530. Part of the instructions can also be directed to the register 1632. In one aspects of the present disclosure the instructions are decoded according to a hardwired method, and in another aspect of the present disclosure the instructions are decoded according to a microprogram that translates instructions into sets of CPU configuration signals that are applied sequentially over multiple clock pulses. After fetching and decoding the instructions, the instructions are executed using the arithmetic logic unit (ALU) 1634 that loads values from the register 1632 and performs logical and mathematical operations on the loaded values according to the instructions. The results from these operations can be feedback into the register and/or stored in the fast memory 1640. According to certain aspects of the present disclosures, the instruction set architecture of the CPU 1530 can use a reduced instruction set architecture, a complex instruction set architecture, a vector processor architecture, a very large instruction word architecture. Furthermore, the CPU 1530 can be based on the Von Neuman model or the Harvard model. The CPU 1530 can be a digital signal processor, an FPGA, an ASIC, a PLA, a PLD, or a CPLD. Further, the CPU 1530 can be an x86 processor by Intel or by AMD; an ARM processor, a Power architecture processor by, e.g., IBM; a SPARC architecture processor by Sun Microsystems or by Oracle; or other known CPU architecture.

Referring again to FIG. 15, the data processing system 1580 can include that the SB/ICH 1520 is coupled through a system bus to an I/O Bus, a read only memory (ROM) 1556, universal serial bus (USB) port 1564, a flash binary input/output system (BIOS) 1568, and a graphics controller 1558. PCI/PCIe devices can also be coupled to SB/ICH 1520 through a PCI bus 1562.

The PCI devices may include, for example, Ethernet adapters, add-in cards, and PC cards for notebook computers. The Hard disk drive 1560 and CD-ROM 1556 can use, for example, an integrated drive electronics (IDE) or serial advanced technology attachment (SATA) interface. In one aspect of the present disclosure the I/O bus can include a super I/O (SIO) device.

Further, the hard disk drive (HDD) 1560 and optical drive 1566 can also be coupled to the SB/ICH 1520 through a system bus. In one aspects of the present disclosure, a keyboard 1570, a mouse 1572, a parallel port 1578, and a serial port 1576 can be connected to the system bus through the I/O bus. Other peripherals and devices that can be connected to the SB/ICH 1520 using a mass storage controller such as SATA or PATA, an Ethernet port, an ISA bus, an LPC bridge, SMBus, a DMA controller, and an Audio Codec.

Moreover, the present disclosure is not limited to the specific circuit elements described herein, nor is the present disclosure limited to the specific sizing and classification of these elements. For example, the skilled artisan will appreciate that the circuitry described herein may be adapted based on changes on battery sizing and chemistry or based on the requirements of the intended back-up load to be powered.

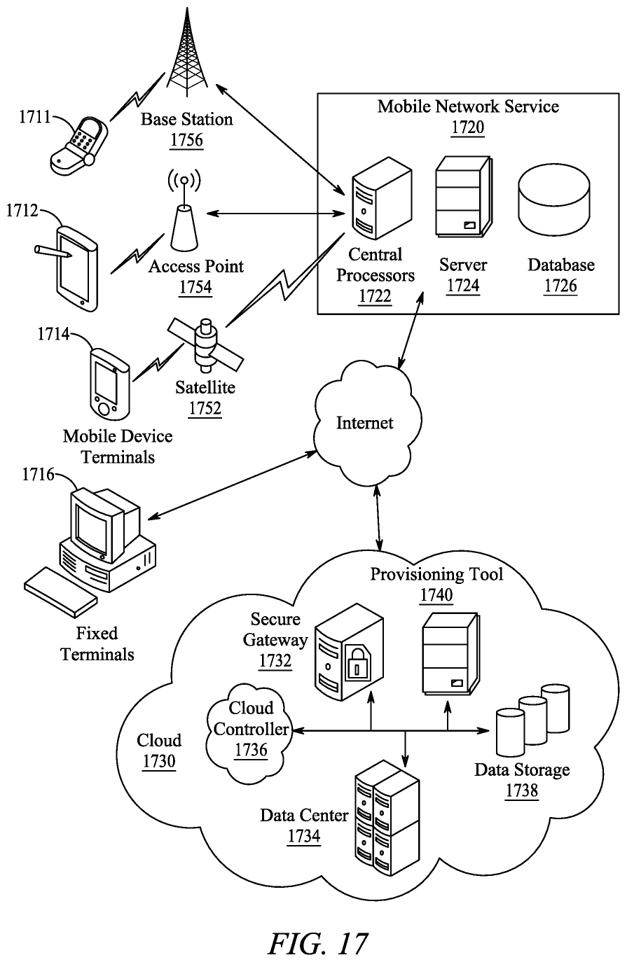

The functions and features described herein may also be executed by various distributed components of a system. For example, one or more processors may execute these system functions, wherein the processors are distributed across multiple components communicating in a network. The distributed components may include one or more client and server machines, which may share processing, as shown by FIG. 17, in addition to various human interface and communication devices (e.g., display monitors, smart phones, tablets, personal digital assistants (PDAs)). More specifically, FIG. 17 illustrates client devices including smart phone 1711, tablet 1712, mobile device terminal 1714 and fixed terminals 1716. These client devices may be commutatively coupled with a mobile network service 1720 via base station 1756, access point 1754, satellite 1752 or via an internet connection. Mobile network service 1720 may comprise central processors 1722, server 1724 and database 1726. Fixed terminals 1716 and mobile network service 1720 may be commutatively coupled via an internet connection to functions in cloud 1730 that may comprise security gateway 1732, data center 1734, cloud controller 1736, data storage 1738 and provisioning tool 1740. The network may be a private network, such as a LAN or WAN, or may be a public network, such as the Internet. Input to the system may be received via direct user input and received remotely either in real-time or as a batch process. Additionally, some aspects of the present disclosures may be performed on modules or hardware not identical to those described. Accordingly, other aspects of the present disclosures are within the scope that may be claimed.

The above-described hardware description is a non-limiting example of corresponding structure for performing the functionality described herein.

Obviously, numerous modifications and variations of the present disclosure are possible in light of the above teachings. It is therefore to be understood that within the scope of the appended claims, the invention may be practiced otherwise than as specifically described herein.

1. A non-contact system for operating elevator buttons, comprising:
a first non-contact device including:
a motor;
a battery switchably connected to the motor;
a voltage regulator connected to the battery;
a motor shaft connected to the motor, wherein the motor shaft is configured to rotate when the battery is connected to the motor;
a dual arm connected to the motor shaft at a center of the arm, wherein the dual arm has a first end and a second end, wherein the dual arm is configured to rotate with the motor shaft;
a first protrusion connected to the first end, wherein the first protrusion extends perpendicularly from the first end, wherein the first protrusion is configured to depress a first elevator button;
a second protrusion connected to the second end, wherein the second protrusion extends perpendicularly from the second end, wherein the second protrusion is configured to depress a second elevator button;
a switch operatively connected to the motor;
a first proximity sensor configured to detect a first finger gesture and generate a first signal;
a second proximity sensor configured to detect a second finger gesture and generate a second signal;
a microcontroller connected to the switch, the first proximity sensor and the second proximity sensor, wherein the microcontroller includes an electrical circuitry, a memory including program instructions and at least one processor configured to execute the program instructions to:
actuate the switch to cause the motor to rotate the dual arm in a first direction to press the first elevator button when the first signal is received; and
actuate the switch to cause the motor to rotate the dual arm in a second direction to press the second elevator button when the second signal is received, wherein the second direction is rotationally opposite the first direction.

2. The non-contact system of claim 1, wherein the first non-contact device further comprises:
a first light emitting diode; and
a second light emitting diode;
wherein the microcontroller is connected to the first light emitting diode and the second light emitting diode, wherein the microcontroller is configured to switch ON the first light emitting diode when the first signal is received and switch ON the second light emitting diode when the second signal is received.

3. The non-contact system of claim 2, wherein the first non-contact device further comprises:
a housing including a top surface, a bottom surface, a first side, a second side perpendicular to the first side, a third side opposite the first side, and a fourth side opposite the second side:
wherein the top surface is configured to hold the first proximity sensor, the second proximity sensor, the first light emitting diode and the second light emitting diode;
a connector socket located in the second side;
a connector plug located in the fourth side;
an opening for the motor shaft located in a center of the first side; and
an interior cavity configured to hold the motor, battery, the voltage regulator and connection wiring.

4. The non-contact system of claim 1, wherein the first non-contact device further comprises:
a near field communication receiver operatively connected to the microcontroller, wherein the near field communication receiver is configured to receive first commands from a mobile application installed on a mobile computing device within a near field communication range when the near field communication receiver is switched ON by the microcontroller; and
the microcontroller is further configured to switch the motor to rotate the dual arm in one of the first direction to press the first elevator button and the second direction to press the second elevator button based on the first commands.

5. The non-contact system of claim 4, wherein the microcontroller is further configured to actuate the switch to cause the motor to rotate the motor shaft such that:
the dual arm extends in a plane normal to the elevator surface when in a rest position;
the dual arm rotates from the rest position to a first operating position at a first angle in the range of −10 degrees to −30 degrees in the first direction when the first signal is received; and
the dual arm rotates from the rest position to a second operating position at a second angle in the range of 10 degrees to 30 degrees in the second direction when the second signal is received.

6. The non-contact system of claim 5, wherein the microcontroller is further configured to:
receive second commands from the mobile application, wherein the second commands define the first angle and the second angle; and
one of rotate the dual arm to the first operating position at the first angle and rotate the dual arm to the second operating position at the second angle, based on the second commands.

7. The non-contact system of claim 6, wherein the first non-contact device further comprises:
a buffer circuit connected between the microcontroller and the motor, wherein the buffer circuit is configured to store a usage count and increase the usage count when one of the first signal and the second signal are received by the microcontroller.

8. The non-contact system of claim 7, further comprising a second non-contact device identical to the first non-contact device, wherein the first non-contact device is configured as a master device and the second non-contact device is configured as a slave device, wherein the connector plug of the second non-contact device is connected to the connector socket of the first non-contact device.

9. The non-contact system of claim 8, further comprising a third non-contact device identical to the first non-contact device, wherein the first non-contact device is configured as a master device and the third non-contact device is configured as a slave device, wherein the connector socket of the third non-contact device is connected to the connector plug of the first non-contact device.

10. The non-contact system of claim 9, wherein the near field communication receiver of the first non-contact device is turned ON and is operatively connected to receive the first commands and the second commands from the mobile application, and the near field communication receivers of the second non-contact device and the third non-contact device are turned OFF.

11. The non-contact system of claim 10, wherein the first non-contact device comprises:
a pair of floor numbers stored in the memory for each of the first non-contact device, the second non-contact device and the third non-contact device;
wherein the microcontroller is configured to:
determine whether the first commands match one of the pair of floor numbers for the first non-contact device;
when the first commands match a floor number for the first non-contact device, actuate the switch to cause the motor to rotate the dual arm in one of a first direction to press the first elevator button and a second direction to press the second elevator button;
when the first commands do not match a floor number for the first non-contact device, determine whether the first commands match one of the floor numbers of the second non-contact device and transmit the first commands to the second non-contact device; and
when the first commands do not match a floor number for the first non-contact device or a floor number of the second non-contact device, determine whether the first commands match one of the floor numbers of the third non-contact device and transmit the first commands to the third non-contact device.

12. The non-contact system of claim 11, wherein the microcontroller of the first non-contact device is configured to:
when the first commands match a floor number for the first non-contact device, use the second commands to adjust the angle of the dual arm;
when the first commands do not match a floor number for the first non-contact device, determine whether the first commands match one of the floor numbers of the second non-contact device and transmit the second commands to the second non-contact device; and
when the first commands do not match a floor number for the first non-contact device or a floor number of the second non-contact device, determine whether the first commands match one of the floor numbers of the third non-contact device and transmit the second commands to the third non-contact device.

13. The non-contact system of claim 11, further comprising:
when the first commands match a floor number for the first non-contact device, the microcontroller of the first non-contact device is configured increase the usage count of the first non-contact device by one;
when the first commands do not match a floor number for the first non-contact device, the microcontroller of the first non-contact device is configured to determine whether the first commands match one of the floor numbers of the second non-contact device and transmit the first commands to the second non-contact device, wherein the microcontroller of the second non-contact device is configured to increase its usage count by one; and
when the first commands do not match a floor number for the first non-contact device, the microcontroller of the first non-contact device is configured to determine whether the first commands match one of the floor numbers of the third non-contact device and transmit the first commands to the third non-contact device, wherein the microcontroller of the third non-contact device is configured to increase its usage count by one.

14. A stackable master-slave non-contact system for operating elevator buttons, comprising:
a plurality of non-contact devices, each non-contact device including:
a motor;
a battery switchably connected to the motor;
a voltage regulator connected to the battery;
a motor shaft connected to the motor, wherein the motor shaft is configured to rotate when the battery is connected to the motor;
a dual arm connected to the motor shaft at a center of the arm, wherein the dual arm has a first end and a second end, wherein the dual arm is configured to rotate with the motor shaft;
a first protrusion connected to the first end, wherein the first protrusion extends perpendicularly from the first end, wherein the first protrusion is configured to depress a first elevator button;
a second protrusion connected to the second end, wherein the second protrusion extends perpendicularly from the second end, wherein the second protrusion is configured to depress a second elevator button;
a switch operatively connected to the motor;
a first proximity sensor configured to detect a first finger gesture and generate a first signal;
a second proximity sensor configured to detect a second finger gesture and generate a second signal;
a microcontroller connected to the switch, the first proximity sensor and the second proximity sensor, wherein the microcontroller includes an electrical circuitry, a memory including program instructions and at least one processor configured to execute the program instructions to:
actuate the switch to cause the motor to rotate the dual arm in a first direction to press the first elevator button when the first signal is received; and
actuate the switch to cause the motor to rotate the dual arm in a second direction to press the second elevator button when the second signal is received,
wherein the second direction is rotationally opposite the first direction;
a first light emitting diode;
a second light emitting diode;
wherein the microcontroller is connected to the first light emitting diode and the second light emitting diode, wherein the microcontroller is configured to switch ON the first light emitting diode when the first signal is received and switch ON the second light emitting diode when the second signal is received;
a near field communication receiver operatively connected to the microcontroller, wherein the near field communication receiver is configured to receive first commands from a mobile application installed on a mobile computing device within a near field communication range when the near field communication receiver is turned ON;
wherein the microcontroller is further configured to switch the motor to rotate the dual arm in one of the first direction to press the first elevator button and the second direction to press the second elevator button based on the first commands;
a buffer circuit connected between the microcontroller and the motor, wherein the buffer circuit is configured to store a usage count and increase the usage count when one of the first signal and the second signal are received by the microcontroller,
wherein a first non-contact device of the plurality of non-contact devices is configured as a master device having the near field communication device turned ON; and
wherein the remaining plurality of non-contact devices are configured as slave devices having the near field communication device turned OFF.

15. The stackable master-slave non-contact system of claim 14, comprising:
wherein each non-contact device is surrounded by a housing including a top surface, a bottom surface, a first side, a second side perpendicular to the first side, a third side opposite the first side, and a fourth side opposite the second side:
wherein the top surface is configured to hold the first proximity sensor, the second proximity sensor, the first light emitting diode and the second light emitting diode;
a connector socket located in the second side;
a connector plug located in the fourth side;
an opening for the motor shaft located in a center of the first side; and
an interior cavity configured to hold the motor, battery, the voltage regulator and connection wiring.

16. The stackable master-slave non-contact system of claim 15, wherein:
each slave device is connected by one of the connector socket and the connector plug to one of the connector plug and the connector socket respectively of the master device, or
each slave device is connected by one of the connector socket and the connector plug to one of the connector plug and the connector socket respectively of an adjacent slave device.

17. The stackable master-slave non-contact system of claim 16, further comprising:
a pair of floor numbers stored in the memory of the master device for each of the master device and the slave devices;
wherein the near field communication receiver of the master device is configured to receive first commands and second commands from a mobile application installed on a mobile computing device within a near field communication range when the near field communication receiver is switched ON by the microcontroller;
wherein the microcontroller is configured to:
determine whether the first commands match one of the pair of floor numbers for the master device;
when the first commands match a floor number for the master device, actuate the switch to cause the motor to rotate the dual arm to the first operating position at the first angle to press the first elevator button and rotate the dual arm to the second operating position at the second angle to press the second elevator button based on the first commands and the second commands;
when the first commands do not match a floor number for the master device, determine whether the first commands match one of the floor numbers of a slave device connected to the connector socket and transmit the first commands and the second commands to the slave device connected to the connector socket;
when the first commands do not match a floor number for the master device or a floor number of the slave device connected to the connector socket, determine whether the first commands match one of the floor numbers of the slave device connected to the connector plug and transmit the first commands and the second commands to the slave device connected to the connector plug;
when the first commands do not match one of a floor number for the master device, a floor number of the slave device connected to the connector plug and a floor number of the slave device connected to the connector socket, determine which one of a slave device connected in series with the slave device connected to the connector plug and a slave device connected in series with the slave device connected to the connector socket has a floor number which matches the first commands, and transmit the first commands and the second commands to the slave device which has a floor number which matches the first commands; and
wherein the microcontroller of each of the plurality of non-contact devices is configured to adjust an angle of the dual arm to a first angle and a second angle based on the second commands.

18. The stackable master-slave non-contact system of claim 17, wherein the buffer circuit of each of the plurality of non-contact devices is configured to increase its usage count by one when the first commands are received.

19. A method for using a stackable master-slave non-contact system for operating elevator buttons, comprising:
operatively stacking a plurality of non-contact devices onto the surface of an elevator control panel so that the each of the plurality of non-contact devices is adjacent to a pair of elevator buttons;
for each of the plurality of non-contact devices:
monitoring, by a microcontroller of the non-contact device, a first proximity sensor for a first signal and a second proximity sensor for a second signal;
receiving, by the microcontroller one of the first signal and the second signal;
updating, by a buffer circuit connected to the microcontroller, a usage count of a buffer circuit upon receiving one of the first signal and the second signal;
actuating, by the microcontroller, a motor configured to rotate a dual arm connected to the motor in one of a first rotational direction such that a first protrusion presses a first elevator button based on the first signal and in a second rotational direction such that a second protrusion presses a second elevator button based on the second signal; and
switching ON a first light emitting diode adjacent to the first proximity sensor upon receiving the first signal and switching ON a second light emitting diode adjacent to the second proximity sensor upon receiving the second signal.

20. The method of claim 19, further comprising:
connecting the plurality of non-contact devices together in a series configuration that matches a pattern of the elevator buttons;
designating one of the non-contact devices as a master device;
turning ON a near field communication receiver of the master device;
connecting the near field communication receiver with a mobile application installed on a mobile computing device within a near field communication range;
receiving, from the mobile application, a first set of commands for pressing an elevator button for a selected floor;
receiving, from the mobile application, a second set of commands for adjusting an angle of a dual arm having a first protrusion configured to press a first elevator button and a second protrusion configured to press one of a second elevator button adjacent the first elevator button for the selected floor;
updating the usage counter based on receiving the first set of commands;
determining if the selected floor matches a floor number stored in a memory of the master device;
when the selected floor matches the floor number stored in the memory, actuating the motor to rotate the dual arm to press one of the first elevator button and the second elevator button based on the floor number; and
when the selected floor does not match the floor number stored in the memory, transmitting the first commands and the second commands to each slave device in the series connection of slave devices, until the microcontroller of one of the slave devices, determines there is a match to a floor number stored in its memory, and actuating the motor of the one of the slave devices to rotate the dual arm to press one of the first elevator button and the second elevator button based on the floor number.
